(19) United States
(12) Patent Application Publication
(10) Pub. No.: US 2022/0080550 A1
(43) Pub. Date: Mar. 17, 2022

(54) POLISHING PAD HAVING PATTERN STRUCTURE FORMED ON POLISHING SURFACE, POLISHING DEVICE INCLUDING SAME, AND METHOD FOR MANUFACTURING POLISHING PAD

(71) Applicant: KOREA INSTITUTE OF INDUSTRIAL TECHNOLOGY, Cheonan-si Chungcheongnam-do (KR)

(72) Inventors: Hyoung Jae KIM, Busan (KR); Tae Kyung LEE, Yangsan-si Gyeongsangnam-do (KR); Do Yeon KIM, Busan (KR); Pil Sik KANG, Changwon-si Gyeongsangnam-do (KR)

(21) Appl. No.: 17/536,100

(22) Filed: Nov. 29, 2021

Related U.S. Application Data
(63) Continuation of application No. PCT/KR2020/006523, filed on May 19, 2020.

(30) Foreign Application Priority Data
May 29, 2019 (KR) 10-2019-0063360
May 29, 2019 (KR) 10-2019-0063372
May 29, 2019 (KR) 10-2019-0063380

(51) Int. Cl. B24B 37/26; B24B 37/22

(52) U.S. Cl. CPC B24B 37/26; B24B 37/22

(57) ABSTRACT

A polishing pad, a polishing device including the same, and a method of preparing a polishing pad are provided. The polishing pad includes a support layer, and a pattern layer disposed on one surface of the support layer, and the pattern layer includes a plurality of protrusion patterns spaced apart from each other on the support layer, and has a greater rigidity than a rigidity of the support layer.

### TECHNICAL FIELD

The present invention relates to a polishing pad having a pattern structure formed on a polishing surface, a polishing device including the same, and a method of preparing a polishing pad. More particularly, the present invention relates to a polishing pad having an improved removal rate, a polishing device including the same and thus having an improved removal rate, and a method of preparing a polishing pad having an improved removal rate.

### BACKGROUND ART

A chemical mechanical polishing (CMP) process is required to manufacture highly integrated circuit devices such as a semiconductor, a display, and the like. In the chemical mechanical polishing process, a polishing target substrate, e.g., a wafer substrate, is brought into pressure contact with a rotating polishing pad and, at the same time, polishing is performed using chemical reaction with slurry. The chemical mechanical polishing process is intended to planarize a polishing target surface or to remove an unnecessary layer.

The characteristics of the polishing process may be expressed as a removal rate (RR), non-uniformity (NU), scratch of a polishing target, planarization of the polishing target, or the like. Among them, the removal rate is one of the most important characteristics of the polishing process, and the shape of the polishing surface of a polishing pad, a slurry composition, the temperature of a polishing platen, and the like are known as major factors of the removal rate.

A conventional polishing device includes a conditioner to maintain the characteristics of the surface of the polishing pad, i.e., the polishing surface. The conditioner may be located eccentric with respect to the axis of rotation of the polishing pad, and the conditioner may be configured to be in contact with the polishing surface of the polishing pad. Cutting particles made of diamond or the like are disposed on the surface of the conditioner in contact with the polishing pad, and an uneven structure may be formed on the polishing pad surface due to the cutting particles. That is, during the polishing process, the conditioner continuously may polish the polishing surface of the polishing pad to maintain the surface roughness of the polishing pad in an optimal state, and the polishing device including the polishing pad may maintain an approximately constant removal rate.

### DISCLOSURE

### Technical Problem

However, the polishing pad is continuously worn as the polishing process is performed, so that the uneven structure of the surface and the surface roughness may become non-uniform. If the surface roughness is too small, the actual contact area that is actually in contact with the polishing target substrate increases or the flow of polishing liquid slurry is disturbed. On the contrary, if the surface roughness is too large, required planarization may not be satisfied due to non-uniform contact with the polishing target substrate, and scratches may occur on the polishing target. The problem of non-uniformity of the polishing surface is a factor that reduces the lifetime and durability of the polishing pad.

Particularly, such a problem may become serious as a patterned substrate such as a semiconductor or the like becomes highly integrated. For example, a high degree of planarization is required to form a shallow trench isolation (STI) structure for high integration of semiconductors. In the shallow trench isolation structure, global planarization is required, which may directly affect semiconductor characteristics. However, the conventional polishing pad is vulnerable to defects such as dishing, erosion, and the like due to a durability problem, and such a problem may cause a serious process failure when the surface of a wafer or the like has a slight curvature. Therefore, there is an urgent demand for development of a polishing pad that may be applied even when a high level of planarization is required as in a shallow trench isolation process.

Accordingly, aspects of the present invention provide a polishing pad capable of exhibiting a stable topography of a polishing surface despite a continued polishing process. Accordingly, there is provided a polishing pad capable of improving usage efficiency of polishing liquid slurry while ensuring excellent removal rate and uniformity.

Furthermore, there is provided a polishing pad capable of controlling a removal rate depending on a polishing target from a novel factor that may affect the removal rate.

Aspects of the present invention also provide a polishing device capable of improving usage efficiency of slurry while ensuring excellent removal rate and uniformity.

Aspects of the present invention also provide a method of preparing a polishing pad capable of improving usage efficiency of slurry while ensuring excellent removal rate and uniformity.

It should be noted that aspects of the present invention are not limited to the above-mentioned aspects, and other unmentioned aspects of the present invention will be clearly understood by those skilled in the art from the following descriptions.

### Technical Solution

According to an exemplary embodiment of the invention, there is provided a polishing pad. The polishing pad comprises: a support layer; and a pattern layer disposed on one surface of the support layer, including a plurality of protrusion patterns spaced apart from each other on the support layer, and having a rigidity greater than a rigidity of the support layer.

In a plan view, a polishing area occupied by the protrusion patterns may be about 1.0% to about 40.0% with respect to a total area.

In a unit area (1 mm²) in the plan view, a circumferential length per unit area formed by planar circumferences of the protrusion pattern may be about 1.0 mm/mm² to about 50.0 mm/mm².

A protrusion pattern of the plurality of protrusion patterns may include: a first portion having a vertical side surface; and a second portion disposed between the first portion and the support layer and having an inclined sidewall, wherein a height of the first portion is about 0.01 to about 0.5 mm.

The protrusion patterns may be regularly and repeatedly arranged in the plan view, and be repeatedly arranged along at least two directions.

In the plurality of protrusion patterns regularly arranged, a certain protrusion pattern may include a plurality of sub-patterns having the same shape or different shapes. The plurality of sub-patterns may be regularly arranged to form the certain protrusion pattern.

And in the plurality of sub-patterns, a certain sub-pattern has an approximately ‘+’ shape, and the plurality of sub-patterns are spaced apart from each other.

In the plurality of protrusion patterns regularly arranged, a certain protrusion pattern may include a plurality of sub-patterns having the same shape or different shapes.

The plurality of sub-patterns forming the certain protrusion pattern may be regularly arranged, and a repeated arrangement direction of the plurality of protrusion patterns may intersect a repeated arrangement direction of the plurality of sub-patterns.

One surface of the polishing pad may have a trench formed at least in the pattern layer, the polishing pad may be a circular shape in a plan view, the trench may include a plurality of first trenches extending radially from a center of the circular polishing pad, and the first trenches may extend at least in a first direction and a second direction perpendicular to the first direction.

A maximum depth of the trench may be greater than a maximum height of each of the protrusion pattern.

The trench may further include a plurality of second trenches arranged concentrically with respect to the center of the circular polishing pad, and a width of each of the second trenches may be smaller than a width of each of the first trenches.

The trench may further include a plurality of third trenches extending to intersect the first trenches and the second trenches and extending to intersect a tangential direction of a rotation direction of the polishing pad.

And a width of each of the third trenches is smaller than the width of each of the second trenches.

In an exemplary embodiment, the protrusion patterns may be regularly and repeatedly arranged in the plan view, and a repeated arrangement direction of the protrusion patterns may intersect the first direction and the second direction.

The protrusion patterns may be regularly and repeatedly arranged in a plan view. In the plurality of protrusion patterns, a certain protrusion pattern may include a plurality of sub-patterns having the same shape or different shapes.

The plurality of sub-patterns forming the certain protrusion pattern may be regularly arranged, and a repeated arrangement direction of the sub-patterns intersects the first direction and the second direction.

In an exemplary embodiment, the pattern laver may further include: a plurality of bases spaced apart from each other. The plurality of protrusion patterns may be spaced apart from each other on upper surfaces of the bases, and a separation space between two adjacent bases of the plurality of bases may form a trench, and the one surface of the support layer may be at least partially exposed through the separation space.

In an exemplary embodiment, the pattern layer may further include: a base. The plurality of protrusion patterns may be spaced apart from each other on one surface of the base, and the one surface of the base has a trench, a maximum thickness of the base is about 1.0 mm to about 3.0 mm, and the trench of the base does not penetrate the base.

In an exemplary embodiment, the one surface of the support layer may have a trench, and the trench of the support layer may not overlap the protrusion pattern in the plan view, and a maximum depth of the trench of the support layer may be about 1% to about 50% of a maximum thickness of the support layer.

The pattern layer may further include: a plurality of bases spaced apart from each other. The plurality of protrusion patterns may be spaced apart from each other on upper surfaces of the bases, and a separation space between two adjacent bases of the plurality of bases may form a trench, and the trench of the support layer may be connected to the trench of the base.

The support layer and the pattern layer may be made of different materials.

And, the polishing pad may further include a bonding layer interposed between the support layer and the pattern layer.

According to an exemplary embodiment of the invention, there is provided a polishing device. The polishing device includes: a polishing platen configured to rotate; and a polishing pad disposed on the polishing platen. The polishing pad includes: a support layer; and a pattern layer disposed on one surface of the support laver, including a plurality of protrusion patterns spaced apart from each other on the support layer, and having a rigidity greater than a rigidity of the support layer.

According to an exemplary embodiment of the invention, there is provided a method of preparing a polishing pad. The method, includes: unwinding a support layer from an unwinding roll; disposing a pattern layer on one surface of the support layer, the pattern layer including a plurality of protrusion patterns spaced apart from each other; and forming a trench at least in the pattern layer such that at least a part of the protrusion patterns is removed.

The details of other embodiments are included in the detailed description.

### Advantageous Effects

In accordance with embodiments of the present invention, it is possible to stably exhibit the surface roughness or the topography of the polishing surface despite the continued polishing process, and also possible to improve the removal rate and the polishing uniformity. Further, even if the surface of the polishing target has a slight curvature, it is possible to follow the curvature of the surface of the target in a vertical direction, thereby improving the removal rate and the polishing uniformity.

In addition, it is possible to control the removal rate from the factors such as the pattern structure of the polishing pad surface, the length of the pattern, the contact surface of the pattern, and the like, and also possible to improve the usage efficiency of slurry due to the shape and arrangement of the unique protrusion pattern according to the embodiments of the present invention.

Advantageous effects according to the present invention are not limited to those mentioned above, and various other advantageous effects are included herein.

### DESCRIPTION OF DRAWINGS

FIG. 1 is a perspective view of a polishing device according to one embodiment of the present invention.

FIG. 2 shows a planar layout of the polishing pad of the polishing device of FIG. 1.

FIG. 3 is an enlarged plan view illustrating the arrangement of protrusion patterns of FIG. 2.

FIG. 4 is an enlarged perspective view of area A of FIG. 2.

FIG. 5 is a cross-sectional view taken along line B-B′ of FIG. 4.

FIG. 6 is a schematic view showing a state in which the polishing pad of FIG. 2 is in contact with the polishing target substrate.

FIG. 7 is a schematic view compared with FIG. 6.

FIG. 8 is a schematic view showing a state in which the polishing pad of FIG. 2 is in contact with the polishing target substrate.

FIG. 9 is a schematic view compared with FIG. 8.

FIG. 10 is a cross-sectional view of a polishing pad according to another embodiment of the present invention.

FIG. 11 is a cross-sectional view of a polishing pad according to still another embodiment of the present invention.

FIGS. 12 to 15 are cross-sectional views of a polishing pad according to still other embodiments of the present invention.

FIG. 16 shows a planar layout of a polishing pad according to still another embodiment of the present invention.

FIG. 17 shows a planar layout of a polishing pad according to still another embodiment of the present invention.

FIG. 18 is an enlarged plan view illustrating the arrangement of protrusion patterns of FIG. 17.

FIG. 19 is an enlarged perspective view of area A of FIG. 17.

FIG. 20 shows a planar layout of a polishing pad according to still another embodiment of the present invention.

FIG. 21 is an enlarged plan view illustrating the arrangement of protrusion patterns of FIG. 20.

FIG. 22 is an enlarged perspective view of area A of FIG. 20.

FIG. 23 shows a planar layout of a polishing pad according to still another embodiment of the present invention.

FIG. 24 is an enlarged plan view illustrating the arrangement of protrusion patterns of FIG. 23.

FIG. 25 is an enlarged perspective view of area A of FIG. 23.

FIG. 26 shows a planar layout of a polishing pad according to still another embodiment of the present invention.

FIG. 27 is an enlarged plan view illustrating the arrangement of protrusion patterns of FIG. 26.

FIG. 28 is an enlarged perspective view of area A of FIG. 26.

FIG. 29 shows a planar layout of a polishing pad according to still another embodiment of the present invention.

FIG. 30 is an enlarged plan view illustrating the arrangement of protrusion patterns of FIG. 29.

FIG. 31 is an enlarged perspective view of area A of FIG. 29.

FIG. 32 is a cross-sectional view taken along line B-B′ of FIG. 31.

FIGS. 33 to 38 are cross-sectional views of a polishing pad according to still other embodiments of the present invention.

FIG. 39 shows a planar layout of a polishing pad according to still another embodiment of the present invention.

FIG. 40 is an enlarged plan view illustrating the arrangement of protrusion patterns of FIG. 39.

FIG. 41 is an enlarged perspective view of area A of FIG. 39.

FIG. 42 shows a planar layout of a polishing pad according to still another embodiment of the present invention.

FIG. 43 is an enlarged plan view illustrating the arrangement of protrusion patterns of FIG. 42.

FIG. 44 is an enlarged perspective view of area A of FIG. 42.

FIG. 45 is a schematic diagram of protrusion patterns and/or sub-patterns according to another embodiment of the present invention.

FIG. 46 is a schematic diagram of protrusion patterns and/or sub-patterns according to still another embodiment of the present invention.

FIG. 47 is a process schematic diagram illustrating a method of preparing a polishing pad according to one embodiment of the present invention.

FIG. 48 is microscopic images of polishing pads according to Preparation Example 1.

FIGS. 49 to 51 are microscope images of polishing pads according to Preparation Example 2.

FIG. 52 is a microscope image of a polishing pad prepared according to Comparative Example.

FIGS. 53 to 56 are graphs showing removal rate measurement results according to Test Example 1.

FIGS. 57 and 58 are graphs showing removal rate measurement results according to Test Example 2.

FIG. 59 is a graph showing removal rate measurement results according to Test Example 3.

FIGS. 60 to 62 are graphs showing planarization measurement results according to Test Example 4.

FIG. 63 is a graph showing a polishing temperature according to Test Example 5.

### MODES OF THE INVENTION

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this invention will be thorough and complete and will fully convey the concept of the invention to those skilled in the art, and the present invention will only be defined by the appended claims. That is, various changes may be made to the embodiments of the present invention. However, it is to be understood that the embodiments described below are not intended to limit the embodiments of the present invention, and include all modifications, equivalents, and substitutes thereto.

In the drawings, components may be enlarged or reduced in size, thickness, width, length, and the like for convenience and clarity of description, and thus the present invention is not limited to the illustrated form.

Unless defined otherwise, all technical and scientific terms used herein have the same meaning as commonly understood by one of ordinary skill in the art to which this invention belongs. Further, unless defined otherwise, all terms defined in generally used dictionaries may not be overly interpreted.

Spatially relative terms, such as “above,” “upper,” “on,” “below.” “beneath,” “lower,” and the like, may be used herein for ease of description to describe one element or feature's relationship to another element(s) or feature(s) as illustrated in the figures. It will be understood that the spatially relative terms are intended to encompass different orientations of the device in use in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below.

As used herein, the term “and/or” includes any and all combinations of one or more of the associated listed items. As used herein, the singular forms “a”, “an” and “the” are intended to include the plural forms as well, unless the context clearly indicates otherwise. It will be further understood that the terms “comprises” and/or “comprising,” when used in this specification, specify the presence of stated components, but do not preclude the presence or addition of one or more other components. A numerical range expressed using ‘to’ indicates a numerical range including values stated before and after ‘to’ as the lower and upper limits. A numerical range expressed using ‘about’ or ‘approximately’ indicates a value or a numerical range within 20% of the value or the numerical range stated after ‘about’ or ‘approximately’.

Further, in this specification, a first direction X indicates an arbitrary direction on the plane, and a second direction Y indicates another direction intersecting (e.g., orthogonal to) the first direction X on the plane. Further, a third direction Z means a direction perpendicular to the plane. The terms used in some embodiments, i.e., a first diagonal direction D1, a second diagonal direction D2, a third diagonal direction D3, and a fourth diagonal direction D4, indicate directions belonging to the plane and intersecting the first direction X and the second direction Y. Unless otherwise defined, ‘plane’ indicates the plane to which the first direction X and the second direction Y belong. Further, unless otherwise defined, ‘overlapping’ indicates overlapping in the third direction Z in plan view.

Hereinafter, the present invention will be described in detail with reference to the accompanying drawings.

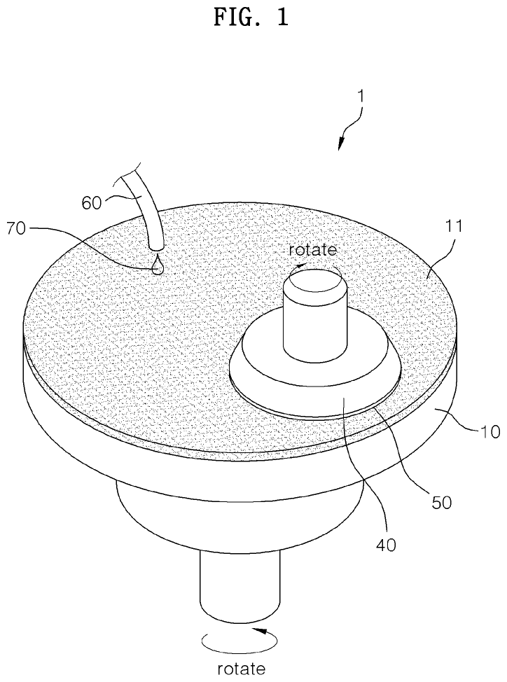

FIG. 1 is a perspective view of a polishing device 1 according to one embodiment of the present invention.

Referring to FIG. 1, the polishing device 1 according to the present embodiment may include a polishing platen 10 connected to a rotation shaft, a polishing pad 11 disposed on the polishing platen 10, and a nozzle 60 for supplying slurry 70 onto the polishing surface of the polishing pad 11. Although the present invention is not limited thereto, the polishing device 1 according to the present embodiment may not require a conditioner for adjusting the surface roughness of the polishing surface of the polishing pad 11.

The polishing platen 10 may be formed in a substantially disc shape and rotate in a counterclockwise direction, for example. Further, the polishing platen 10 may stably support the polishing pad 11 disposed thereon. That is, the polishing platen 10 may function as a rotary table.

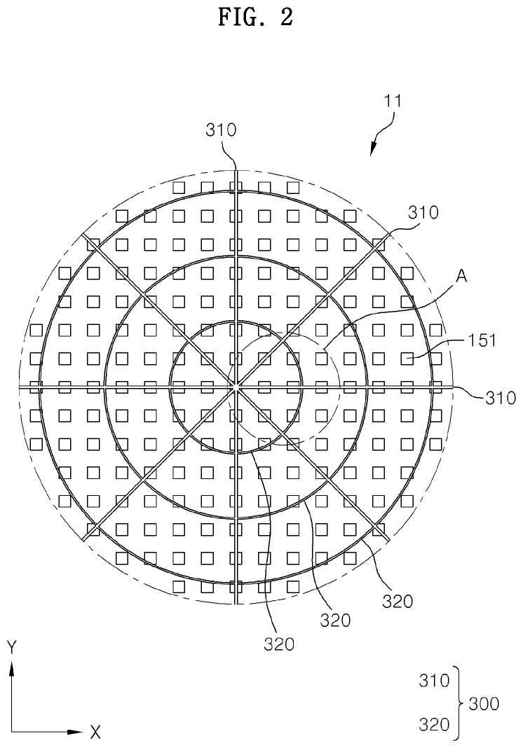

The polishing pad 11 may be disposed on the polishing platen 10. The top surface of the polishing pad 11 in contact with a polishing target substrate 50 may form a polishing surface. Although not shown in FIG. 1, a fine pattern or trench may be formed on the polishing surface (i.e., the top surface) of the polishing pad 11. The polishing pad 11 will be described in detail later with reference to FIG. 2 and the like.

The position of the polishing target substrate 50 may be fixed to be eccentric to the rotation axis of the polishing platen 10 or the rotation axis of the polishing pad 11. The polishing target substrate 50 may be fixed by a carrier 40 connected to the rotation shaft and may rotate together with the carrier 40. The rotation direction of the polishing target substrate 50 may be opposite to the rotation direction of the polishing pad 11, but the present invention is not limited thereto. Further, the polishing target substrate 50 that is polished by the contact with the polishing pad 11 may be a semiconductor wafer substrate, a display substrate, or the like, but the present invention is not limited thereto.

The nozzle 60 may be separated from the polishing pad 11 and may supply the slurry 70 to the polishing surface of the polishing pad 11. In this specification, the term ‘slurry’ may be substantially the same as polishing liquid or polishing particles. The slurry 70 may flow on the polishing surface of the polishing pad 11 by a centrifugal force generated by the rotation of the polishing pad 11, and at least a part of the slurry 70 may penetrate to the space between the polishing pad 1I and the polishing target substrate 50 and contribute to the improvement of the removal rate by chemical reaction.

Hereinafter, the polishing pad 11 will be described in detail with further reference to FIGS. 2 to 5.

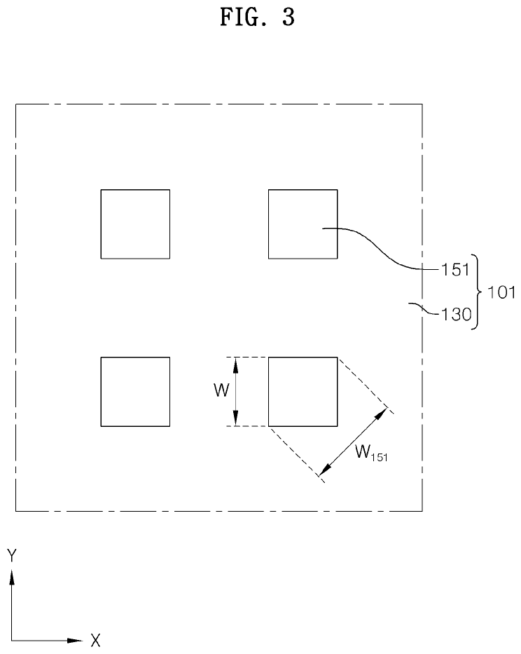

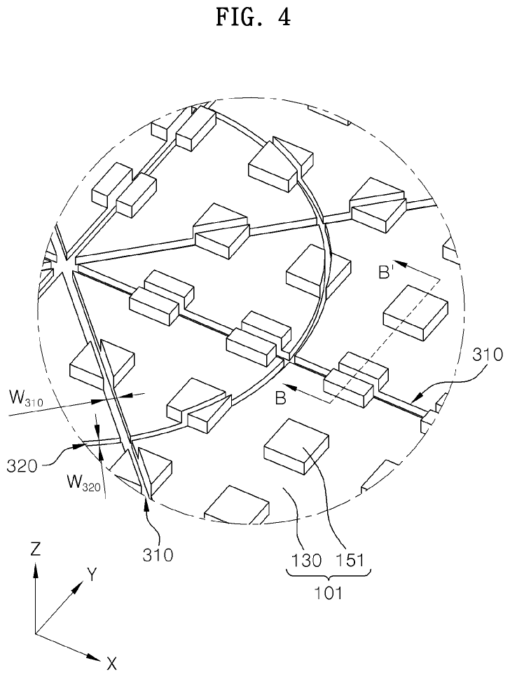

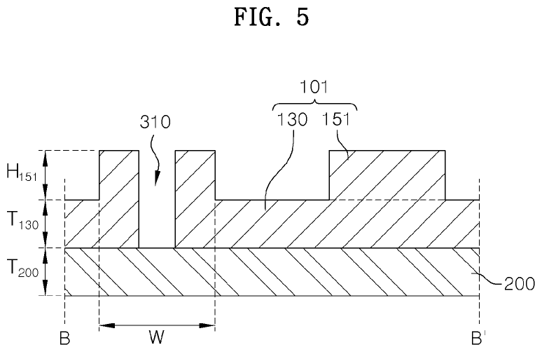

FIG. 2 shows a planar layout of the polishing pad 11 of the polishing device 1 of FIG. 1. FIG. 3 is an enlarged plan view illustrating the arrangement of protrusion patterns 151 of FIG. 2. FIG. 4 is an enlarged perspective view of area A of FIG. 2. FIG. 5 is a cross-sectional view taken along line B-B′ of FIG. 4 to illustrate two protrusion patterns 151 and a first trench 310.

Referring further to FIGS. 2 to 5, the polishing pad 11 according to the present embodiment may have a substantially circular shape in plan view. Further, the polishing pad 11 may include a support layer 200 and a pattern layer 101 disposed on the support layer 200. The entire top surface of the pattern layer 101 may form a polishing surface. Each of the support layer 200 and the pattern layer 101 may include a material having predetermined flexibility.

In an exemplary embodiment, the strength, rigidity, and/or hardness of the support layer 200 may be smaller than the strength, rigidity, and/or hardness of the pattern layer 101. That is, the support layer 200 may have higher flexibility and a lower modulus of elasticity than those of the pattern layer 101. The modulus of elasticity includes a loss modulus and a storage modulus.

Accordingly, even when the surface of the polishing target substrate 50 has a slight curvature and/or even when the polishing pad 11 has a slight curvature, the protrusion patterns 151 formed on the top surface of the polishing pad 11 may be brought into close contact along the curvature of the polishing target substrate 50 to perform polishing. That is, the polishing pad 11 may follow the curvature of the polishing target substrate 50. This will be described later.

The support layer 200 and the pattern layer 101 may be made of the same material or different materials. For example, each of the support layer 200 and the pattern layer 101 may be formed of a polymer material. Examples of the polymer material may include (poly)urethane (PU), (poly)(meth)acrylate, (poly)epoxy, acrylonitrile butadiene styrene (ABS), (poly)etherimide, (poly)amide, (poly)propylene, (poly)butadiene, polyalkylene oxide, (poly)ester, (poly)isoprene, (poly)styrene, (poly)ethylene. (poly)carbonate, polyfluorene, polyphenylene, polyazulene, polypyrene, polynaphthalene, poly-p-phenylenevinylene, polypyrrole, polycarbazole, polyindole, polyaniline, or combinations thereof. In some embodiments, when the support layer 200 and the pattern layer 101 have different rigidities or the like but are made of the same polymer material, a separate bonding layer may not be required between the support layer 200 and the pattern layer 101 due to the physical-chemical bonding force of the support layer 200 and the pattern layer 101. The rigidity or the like of the support layer 200 and the pattern layer 101 may be controlled by a degree of crosslinking of the polymer material or the like, but the present invention is not limited thereto.

The support layer 200 may have a substantially circular shape in plan view, and may serve to support the pattern layer 101 disposed thereon. A minimum thickness T₂₀₀ of the support layer 200 is not particularly limited, but may be, e.g., about 1 mm to 5 mm, or about 2 mm to 4 mm, or about 3 mm. In this specification, the term ‘minimum thickness’, which is a length in the third direction Z, means a thickness of a thinnest portion when a plate-shaped component has a non-uniform thickness. When the thickness of the support layer 200 is smaller than the above range, the support layer 200 may not exhibit sufficient elasticity or strain, and it may be difficult for the polishing pad 11 to follow the curvature of the polishing target substrate 50.

The pattern layer 101 may be disposed on the support layer 200. In an exemplary embodiment, the pattern layer 101 may be directly disposed on the support layer 200 without a separate bonding layer. The pattern layer 101 may include a base 130 and a plurality of protrusion patterns 151 disposed on the base 130. The base 130 and the protrusion pattern 151 are integrally and continuously formed without a physical boundary, and may be made of the same material. The plurality of protrusion patterns 151 may be spaced apart from each other on the base 130.

Although not shown in the drawing, in another embodiment, the base 130 and the protrusion pattern 151 may be made of different materials with a physical boundary. In this case, the strength, rigidity, and/or hardness of the base 130 may be smaller than the strength, rigidity, and/or hardness of the protrusion pattern 151.

The base 130 may be a portion overlapping the plurality of protrusion patterns 151 in the third direction Z. Further, the base 130 may be a portion that substantially occupies most of the area and covers the support layer 200 in plan view. A certain base 130 may be spaced apart from another adjacent base 130 with respect to a trench 300 to be described later. A maximum thickness T₁₃₀ of the base 130 may be within a range of about 0.01 mm to 3.0 mm, or about 0.1 mm to 2.5 mm, or about 0.5 mm to 2.0 mm, or about 1.0 mm to 1.5 mm.

The plurality of protrusion patterns 151 may be disposed on the base 130. The protrusion pattern 151 may have a substantially quadrilateral shape in plan view, but the present invention is not limited thereto. The protrusion pattern 151 may have a substantially quadrilateral shape, and a portion thereof overlapping the trench 300 to be described later may be removed and processed so as not to overlap the trench 300 in the third direction Z.

Further, although FIG. 2 or the like illustrates a state in which the plurality of protrusion patterns 151 are regularly arranged, in another embodiment, the protrusion patterns 151 may have approximately irregular or random arrangement.

In an exemplary embodiment, the protrusion patterns 151 may be repeatedly arranged along at least two directions to form regular arrangement. For example, the protrusion patterns 151 may be repeatedly arranged at the same distance along the first direction X and the second direction Y in an approximately matrix shape.

The size of the protrusion pattern 151 and the like may be major factors affecting the removal rate, the non-uniformity (NU), and the like of the polishing pad 11. The inventors of the present invention have completed the present invention by discovering that the removal rate may be controlled by the circumferential length and/or area of the protrusion pattern 151.

In an exemplary embodiment, in plan view, the polishing area occupied by the protrusion patterns 151 may be about 1.0% or more and 50.0% or less, or about 1.0% or more and less than 50.0%, or about 1.0% or more and 45.0% or less, or about 1.0% or more and 40.0% or less, or about 1.0% or more and 35.0% or less, or about 1.0% or more and 30.0% or less, or about 3.0% or more and 30.0% or less, or about 5.0% or more 30.0% or less, or about 10.0% or more and 30.0% or less with respect to the total area. That is, the lower limit of the polishing area with respect to the total area may be about 1.0%, or about 3.0%, or about 5.0%. Further, the upper limit of the polishing area with respect to the total area may be about 50.0%, or about 45.0%, or about 40.0%, or about 35.0%, or about 30.0%.

In this specification, the term ‘polishing area’ is defined as the total area contributing to polishing due to the contact between the upper ends of the protrusion patterns 151 and the polishing target substrate 50. That is, it may indicate the area occupied by the portion forming the maximum height in the pattern layer 101 of the polishing pad 11.

For example, as shown in FIG. 3, when the planar shape of a certain protrusion pattern 151 is a square shape whose one side has a length of W, the polishing area may be expressed as n×W×W (n being the total number of protrusion patterns) with respect to the total area of the polishing pad 11 in plan view.

When the polishing area is within the above range, an excellent removal rate is exhibited, and the polishing characteristics such as the removal rate and the like may be controlled by changing the arrangement, shape, and/or size of the protrusion patterns 151. Further, when the polishing area is too large, the removal rate may decrease.

Further, in a unit area (1 mm²) in plan view, the circumferential length per unit area formed by the planar circumference of the protrusion pattern 151 may be about 1.0 mm/mm² or more and 250.0 mm/mm² or less (that is, about 1.0 mm/mm² to about 250.0 mm/mm²), or about 1.0 mm/mm² or more and 200.0 mm/mm² or less, or about 1.0 mm/mm² or more and 150.0 mm/mm² or less, or about 1.0 mm/mm² or more and 100.0 mm/mm² or less, or about 1.0 mm/mm² or more and 50.0 mm/mm² or less.

In this specification, the term ‘circumferential length per unit area’ is defined as the total outer length (i.e., perimeter) formed by the polishing area of the protrusion patterns 151 per unit area, e.g., 1 mm².

For example, when it is assumed that the outer quadrangle (indicated as dot-dash broken lines) shown in FIG. 3 has an area of 1 mm², the circumferential length of the protrusion pattern 151 per unit area may be expressed as 4×4×W mm/mm² (four protrusion patterns, four sides per one protrusion pattern, W being the length of one side of the protrusion pattern).

For another example, the circumferential length per unit area may be expressed as the total circumferential length formed by the protrusion patterns 151 belonging to an arbitrary target area to be checked of the polishing pad 11. In this case, if the x-axis represents the target area to be checked (e.g., inspection area) and the y-axis represents the total circumferential length formed by the protrusion patterns 151 in the target area, the slope of the graph may express the circumferential length of the protrusion pattern per unit area.

When the circumferential length of the protrusion pattern 151 per unit area is within the above range, an excellent removal rate may be exhibited. This will be described later together with test examples or the like.

In an exemplary embodiment in which the protrusion pattern 151 has a substantially quadrilateral shape in plan view, a maximum width W₁₅₁ of the protrusion pattern 151 may be formed in a substantially diagonal direction. Although the maximum width W₁₅₁ of the protrusion pattern 151 may vary depending on the planar shape of the protrusion pattern 151, the maximum width W₁₅₁ of the protrusion pattern 151 may be about 0.8 mm or less, or about 0.5 mm or less, or about 0.3 mm or less, for example.

A height Him of the protrusion pattern 151 may affect the polishing characteristics and durability of the polishing pad 11. The minimum height of the protrusion pattern 151 may be within a range of about 0.01 mm or more and 1.5 mm or less, or about 0.01 mm or more and 1.0 mm or less, or about 0.01 mm or more and 0.5 mm or less, or about 0.01 mm or more and 0.3 mm or less. When the height H₁₅₁ of the protrusion pattern 151 exceeds 1.5 mm, in the process in which the polishing pad 11 rotates and is brought into close contact with the polishing target substrate 50, inclination or distortion may occur in a plane direction (e.g., direction to which the first direction X or the second direction Y belongs), so that designed polishing may not be completely performed. On the contrary, when the height His of the protrusion pattern 151 is less than 0.01 mm, the lifetime of the polishing pad 11 may be too short due to damage or abrasion occurring at the upper ends of the protrusion patterns 151 as the polishing process is repeated, which is uneconomical.

Hereinafter, the trench 300 of the polishing pad 11 will be described. One surface (top surface in FIG. 5) of the polishing pad 11 may have the trench 300. The trench 300 may perform a channel function for transporting and discharging the slurry 70 dropped on the top surface of the polishing pad 11. If necessary, the term ‘trench’ used in this specification may be used interchangeably with terms such as a channel, a groove, a recess, or the like.

In an exemplary embodiment, the trench 300 may include the first trench 310 extending in the first direction X and/or the second direction Y. The first trench 310 may have a shape extending substantially radially from the center of the circular polishing pad 11.

In some embodiments, the first trench 310 may extend in a radial direction from the center of the polishing pad 11 as well as in the first direction X and the second direction Y perpendicular to the first direction X, and may further extend in the direction intersecting the first direction X and the second direction Y. FIG. 2 illustrates eight first trenches 310 including two trenches extending in the first direction X, two trenches extending in the second direction Y, and four trenches extending in directions of ±45 degrees with respect to the first direction X. Accordingly, the polishing pad 11 may be partitioned into eight fan-shaped regions having a central angle of approximately 45 degrees. At least some of the first trenches 310 of the polishing pad 11 according to the present embodiment may extend in the same direction as the arranging directions of the protrusion patterns 151, i.e., in the first direction X and the second direction Y.

However, the present invention is not limited thereto, and in another embodiment, twelve first trenches 310 may be formed to partition the polishing pad 11 into twelve fan-shaped regions having a central angle of approximately 30 degrees. In another embodiment, four first trenches 310 may be formed, or sixteen or more first trenches 310 may be formed.

The first trenches 310 may induce the slurry 70 to move or flow in a radially outer direction of the polishing pad 11 due to the centrifugal force generated by the rotation of the polishing pad 11. Accordingly, even when the slurry 70 is dropped without moving the nozzle 60, it is possible to coat the slurry 70 on the entire surface of the polishing pad 11 and prevent the slurry 70 from being excessively aggregated on a part of the surface of the polishing pad 11, thereby improving the utilization efficiency of the slurry. In some embodiments, the depths of the first trenches 310 may increase toward the outer direction of the polishing pad 11.

Further, the trench 300 may further include second trenches 320 arranged concentrically with respect to the center of the circular polishing pad 11. Although FIG. 2 illustrates a case in which three second trenches 320 are formed, the present invention is not limited thereto. A certain second trench 320 may intersect the plurality of first trenches 310. The second trench 320 may induce the slurry 70 to move or flow in the rotation direction of the polishing pad 11 due to the centrifugal force generated by the rotation of the polishing pad 11. Accordingly, even when the slurry 70 is dropped without moving the nozzle 60, it is possible to coat the slurry 70 on the entire surface of the polishing pad 11 and prevent the slurry 70 from being excessively aggregated on a part of the surface of the polishing pad 11.

In addition, in the present embodiment, the first trenches 310 and the second trenches 320 may provide predetermined fluidity to the pattern layer 101, and the protrusion patterns 151 of the polishing pad 11 may follow the curvature of the polishing target substrate 50 as described above.

That is, the top surface of the support layer 200 may be partially exposed by the first trenches 310 and the second trenches 320, and the adjacent pattern layers 101 may be spaced apart from each other with respect to the first trenches 310 and the second trenches 320. That is, the base 130 partitioned and separated with respect to the first trenches 310 or the like may be disposed on one support layer 200. Accordingly, the fluidity in the plane direction may be obtained by the pressure applied to the pattern layer 101 in the third direction Z, and it is possible to more flexibly follow the curved surface of the polishing target substrate in the vertical direction.

In some embodiments, a width W₃₁₀ of the first trench 310 may be greater than a width W₃₂₀ of the second trench 320. For example, the width W₃₁₀ of the first trench 310 and the width W₃₂₀ of the second trench 320 may be about 0.1 mm or more and less than 3.0 mm, or about 0.3 mm or more and 2.5 mm or less, or about 0.5 mm or more and 2.0 mm or less, or about 1.0 mm or more and 1.5 mm or less, and the width W₃₁₀ of the first trench 310 may be greater than the width W₃₂₀ of the second trench 320. In the present specification, the ‘width of the trench’ indicates the shortest length in the direction approximately perpendicular to the extending direction of the trench.

Although the present invention is not limited thereto, the slurry 70 that has moved first in the outer direction of the polishing pad 11 by the first trenches 310 may be moved in the rotation direction of the polishing pad 11 by the second trenches 320. Therefore, it may be preferable that the width W₃₁₀ of the first trench 310 is greater than the width W₃₂₀ of the second trench 320 in order to prevent aggregation of the slurry 70.

Although not shown in the drawing, in some embodiments, the depth, e.g., the maximum depth, of the first trench 310 may be greater than the maximum depth of the second trench 320. In this specification, the ‘depth of the trench’ indicates the shortest length from the reference surface in the third direction Z, and the depth of the first trench 310 indicates the depth from the top surface of the base. That is, the depth of the trench formed in the pattern layer 101 may be measured with the top surface having the maximum level of the base 130 as a reference surface. In the present embodiment, the depth of the first trench 310 may be substantially equal to the thickness T₁₃₀ of the base 130.

Further, the depth T₁₃₀ of the first trench 310 may be greater than the maximum height H₁₅₁ of the protrusion pattern 151. In an exemplary embodiment in which the trench 300 is formed in the pattern layer 101, it may be preferable that the maximum depth T₁₃₀ of the first trench 310 is greater than the height H₁₅₁ of the protrusion pattern 151 of the pattern layer 101 in terms of the fluidity on the pattern layer 101 and the followability to the polishing target substrate.

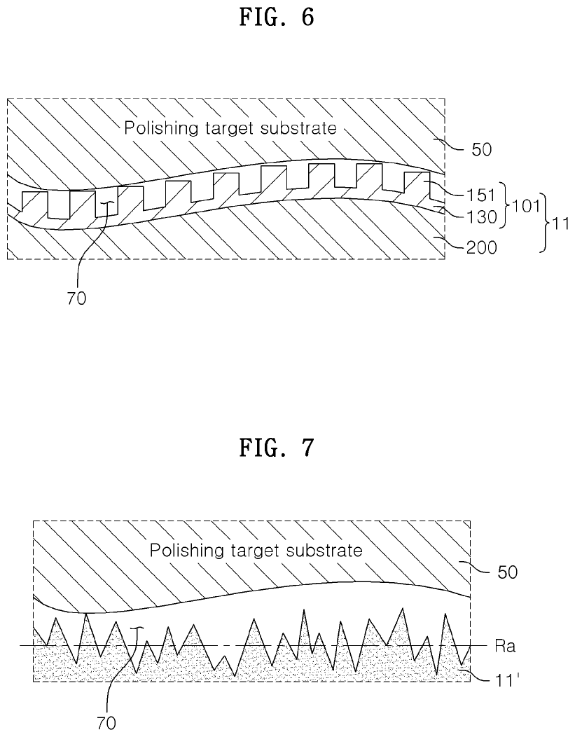

Hereinafter, the followability and polishing characteristics of the polishing pad 11 according to the present embodiment will be described with further reference to FIGS. 6 to 9.

FIG. 6 is an exemplary schematic view showing a state in which the polishing pad 11 is in contact with the polishing target substrate 50, and FIG. 7 is an exemplary schematic view showing a state in which the polishing pad polished by a conventional conditioner is in contact with the polishing target substrate 50.

First, referring to FIG. 6, when the bottom surface of the polishing target substrate 50 has a slight curvature, the polishing pad 11 according to the present embodiment may be elastically deformed in the vertical direction (e.g., in a direction of gravity) due to sufficient flexibility of the support layer 200. Accordingly, the top surfaces of the protrusion patterns 151 forming the polishing surface may be in close contact with the curved surface of the polishing target substrate 50, and the slurry 70 may be evenly distributed to the space between the pattern layer 101 and the polishing target substrate 50, thereby achieving an excellent removal rate.

Further, a relatively higher pressure may be applied to the portion where the polishing target substrate 50 convexly protruding relatively downward is in contact with the polishing pad 11 compared to the portion where the polishing target substrate 50 concavely recessed relatively upward is in contact with the polishing pad 11, so that it is possible to minimize the non-uniformity (NU) and achieve uniform polishing.

Particularly, in the polishing pad 11 according to the present embodiment, the rigidity of the pattern layer 101 is greater than that of the support layer 200, so that when the polishing pad 11 is pressed against the polishing target substrate 50, a degree of deformation of the support layer 200 may be greater than those of the protrusion pattern 151 and the base 130 of the pattern layer 101. As a non-limiting example, only the support layer 200 may be flexibly deformed without substantial deformation of the pattern layer 101. If the protrusion patterns 151 have excessive flexibility and are deformed by a vertical pressure, an intended removal rate may not be exhibited due to deformation of the polishing area of the protrusion patterns 151, vertically tilted deformation, or the like.

Accordingly, the support layer 200 is deformed instead of the pattern layer 101 to follow the curvature of the surface of the polishing target substrate 50 and exhibit an excellent removal rate. Although the present invention is not limited thereto, as a non-limiting example, the pattern layer 101 or the material of the pattern layer 101 including the protrusion patterns 151 may be selected such the maximum rate of change in the plane direction with respect to the pressure in the vertical direction (e.g., the third direction Z) becomes about 20.0% or less, or about 15.0% or less, or about 10.0% or less, or about 5.0% or less.

On the contrary, referring further to FIG. 7, in the case of a conventional polishing pad 11′, it is substantially difficult to exhibit uniform roughness over the entire surface of the polishing pad 11′ even though the surface roughness is maintained by a conditioner (not shown). Accordingly, the polishing pad 11′ cannot be in close contact with the polishing target substrate 50 having a curved surface, which may increase the non-uniformity and even cause a scratch defect.

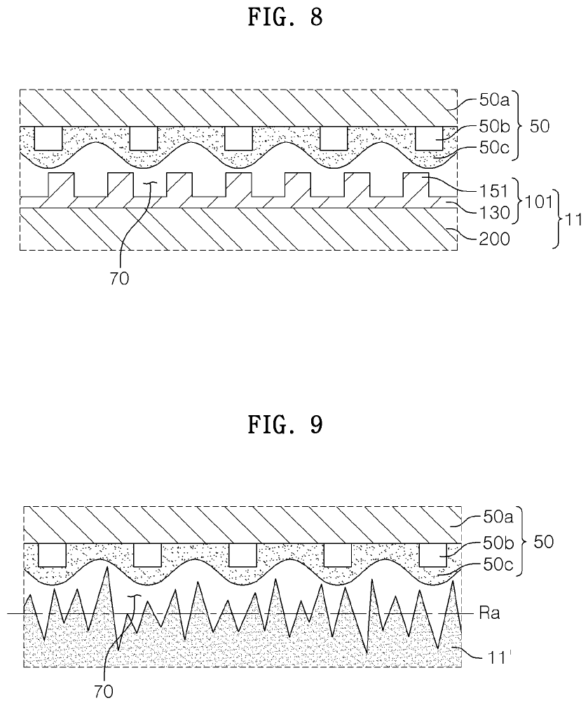

FIG. 8 is another exemplary schematic view showing a state in which the polishing pad 11 is in contact with the polishing target substrate 50, and FIG. 9 is an exemplary schematic view showing a state in which the polishing pad polished by the conventional conditioner is in contact with the polishing target substrate 50. FIGS. 8 and 9 illustrate a case in which the polishing target substrate 50 includes an element pattern 50b disposed on a base substrate 50a and an overcoating layer 50c disposed thereon. The element pattern 50b may be a wiring pattern made of a metal, an active pattern including a semiconductor material, or the like, but is not particularly limited.

First, referring to FIG. 8, when the overcoating layer 50c having very slight curvatures or steps is located on the bottom surface of the polishing target substrate 50, the polishing pad 11 according to the present embodiment may uniformly planarize the overcoating layer 50c due to the uniform height of the upper ends of the pattern layer 101. That is, by selectively polishing only the overcoating layer 50c convexly protruding relatively downward, and minimizing physical pressing on the overcoating layer 50c concavely recessed relatively upward, it is possible to achieve global planarization without damage to the elements of the polishing target substrate 50. Therefore, the polishing pad 11 according to the present embodiment may be applicable to an STI structure process or the like. This will be described later together with Test Example 4.

On the contrary, referring further to FIG. 9, in the case of the conventional polishing pad 11′, it is substantially difficult to exhibit uniform roughness over the entire surface, and in some cases, even the overcoating layer 50c that is recessed relatively upward is polished. Accordingly, the elements of the polishing target substrate 50 are damaged or only partial planarization is achieved, which is not suitable for use in a precision planarization process.

Hereinafter, other embodiments of the present invention will be described. However, a description of the configuration that is the same as or extremely similar to that of the polishing pad 11 according to the above-described embodiment will be omitted, and this will be clearly understood by those skilled in the art from the accompanying drawings. Further, polishing devices to which polishing pads according to other embodiments are applied are easily conceivable.

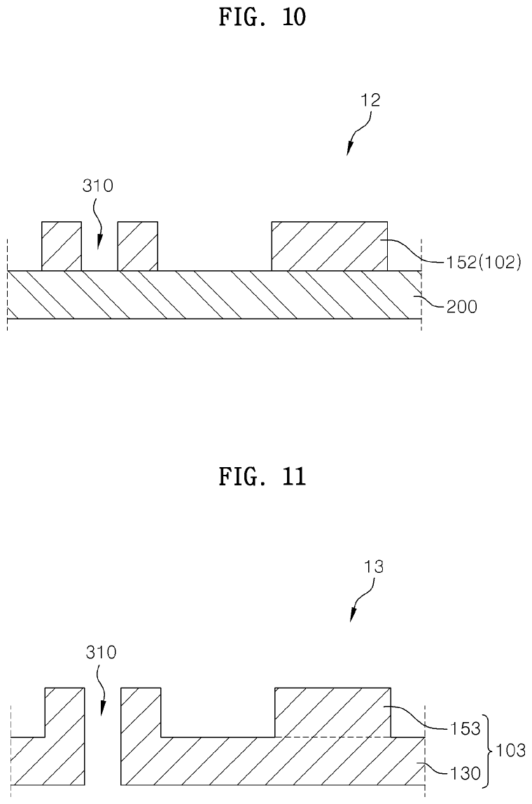

FIG. 10 is a cross-sectional view of a polishing pad 12 according to another embodiment of the present invention, and is a cross-sectional view showing a position corresponding to that of FIG. 5.

Referring to FIG. 10, the polishing pad 12 according to the present embodiment is different from the polishing pad 11 according to the embodiment of FIG. 5 or the like in that it includes the support layer 200 and the pattern layer 102 disposed on the support layer 200, and the pattern layer 102 includes protrusion patterns 152 without having a separate base.

In an exemplary embodiment, the plurality of protrusion patterns 152 may be directly disposed on the support layer 200, and the plurality of protrusion patterns 152 may be spaced apart from each other. Accordingly, the trench including the first trenches 310 may have a depth corresponding to the height of the protrusion pattern 152.

In another embodiment, a trench may be formed on a part of the top surface of the support layer 200 unlike the drawing.

Since the positions, arrangements, sizes, shapes, and materials of the protrusion patterns 152 are the same as those of the above-described protrusion patterns 151, redundant description thereof will be omitted.

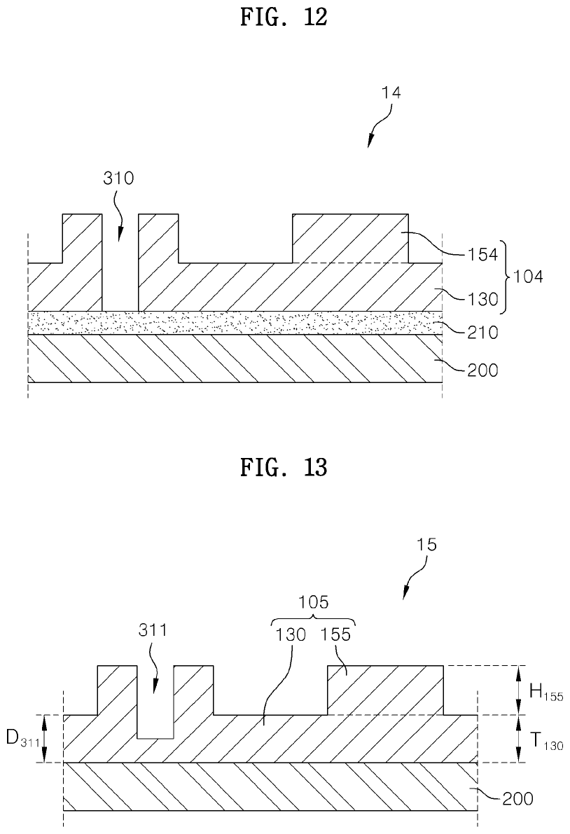

FIG. 11 is a cross-sectional view of the polishing pad 13 according to still another embodiment of the present invention, and is a cross-sectional view showing a position corresponding to that of FIG. 5.

Referring to FIG. 11, the polishing pad 13 according to the present embodiment is different from the polishing pad 11 according to the embodiment of FIG. 5 or the like in that it includes the base 130 and a pattern layer 103 including protrusion patterns 153, but does not have a separate support layer. In this case, the pattern layer 103 may be directly disposed on a polishing platen (not shown).

Since the positions, arrangements, sizes, shapes, and materials of the protrusion patterns 153 are the same as those of the above-described protrusion patterns 151, redundant description thereof will be omitted.

FIG. 12 is a cross-sectional view of a polishing pad 14 according to still another embodiment of the present invention, and is a cross-sectional view showing a position corresponding to that of FIG. 5.

Referring to FIG. 12, the polishing pad 14 according to the present embodiment is different from the polishing pad 11 according to the embodiment of FIG. 5 or the like in that it further includes a bonding layer 210 interposed between the support layer 200 and a pattern layer 104.

The bonding layer 210 may be interposed between the support layer 200 and the pattern layer 104 to couple them. The bonding layer 210 may include a pressure sensitive adhesive (PSA) or the like, but the present invention is not limited thereto. As a non-limiting example, when the support layer 200 and the pattern layer 104 are made of different materials, the support layer 200 and the pattern layer 104 may be coupled with each other via the bonding layer 210.

The top surface of the bonding layer 210 may be partially exposed by the trench including the first trench 310 and the second trench (not shown). Although not shown in the drawing, in another embodiment, a trench may be formed on a part of one surface (the top surface in FIG. 12) of the bonding layer 210. That is, the trench of the bonding layer 210 may overlap and be connected to the trench of the pattern layer 104 to form one trench. Alternatively, the bonding layer 210 disposed at a position overlapping the first trench 310 may be completely removed to form a trench.

Since the positions, arrangements, sizes, shapes, and materials of the protrusion patterns 154 are the same as those of the above-described protrusion patterns 151, redundant description thereof will be omitted.

FIG. 13 is a cross-sectional view of a polishing pad 15 according to still another embodiment of the present invention, and is a cross-sectional view showing a position corresponding to that of FIG. 5.

Referring to FIG. 13, the polishing pad 15 according to the present embodiment is different from the polishing pad 11 according to the embodiment of FIG. 5 or the like in that it has a trench including a first trench 311 and a second trench (not shown), but the trench is partially recessed without completely penetrating the base 130 of the pattern layer 105.

As described above, a height Hiss, e.g., the minimum height, of the protrusion pattern 155 may be within a range of about 0.01 mm or more and 1.5 mm or less, or about 0.01 mm or more and 1.0 mm or less, or about 0.01 mm or more and 0.5 mm or less, or about 0.01 mm or more and 0.3 mm or less. Further, the thickness T₁₃₀, e.g., the maximum thickness, of the base 130 may be within a range of about 0.01 mm to 3.0 mm, or about 0.1 mm to 2.5 mm, or about 0.5 mm to 2.0 mm, or about 1.0 mm to 1.5 mm.

In this case, a depth D₃₁₁, e.g., the maximum depth, of the trench may be smaller than the thickness T₁₃₀ of the base 130. Unlike the drawing, the depth Dan of the trench may be greater than the height Hiss of the protrusion pattern 155. The base 130 may partially remain without being completely penetrated by the first trench 311 or the like. Further, the top surface of the support layer 200 may be completely covered by the pattern layer 105 without being exposed. In this case, the remaining portion may form the minimum thickness of the base 130, but the present invention is not limited thereto.

Since the positions, arrangements, sizes, shapes, and materials of the protrusion patterns 155 are the same as those of the above-described protrusion patterns 151, redundant description thereof will be omitted.

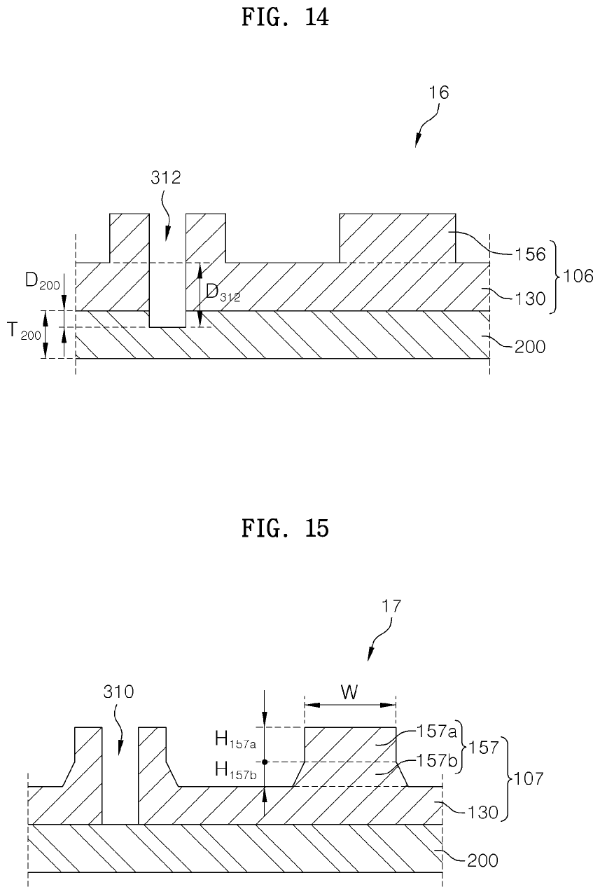

FIG. 14 is a cross-sectional view of a polishing pad 16 according to still another embodiment of the present invention, and is a cross-sectional view showing a position corresponding to that of FIG. 5.

Referring to FIG. 14, the polishing pad 16 according to the present embodiment is different from the polishing pad 11 according to the embodiment of FIG. 5 or the like in that it has a trench including a first trench 312 and a second trench (not shown), and the trench reaches the support layer 200 as well as the pattern layer 106.

In an exemplary embodiment, a trench may be formed on a part of one surface (the top surface in FIG. 14) of the support layer 200. That is, the trench of the support layer 200 may overlap and be connected to the trench of the pattern layer 106 to form one trench.

In this case, a maximum depth D₂₀₀ of the trench of the support layer 200 may have a predetermined relationship with the maximum thickness T₂₀₀ of the support layer 200. For example, the maximum depth D₂₀₀ of the trench of the support layer 200 may be within a range of about 50% or less, or about 40% or less, or about 30% or less, or about 20% or less of the maximum thickness T₂₀₀ of the support layer 200. In addition, the maximum depth D₂₀₀ of the trench of the support layer 200 may be about 1% or more of the maximum thickness T₂₀₀ of the support layer 200.

If the trench is formed in a range exceeding 50% of the maximum thickness T₂₀₀ of the support layer 200, the durability of the support layer 200 may be reduced, and the overall lifetime and durability of the polishing pad 16 may be shortened. Further, in terms of the followability to the curved surface of the polishing target substrate in the vertical direction, which is obtained by the pressing against the polishing target substrate, if the trench of the support layer 200 is formed too deep, the support layer 200 may be deformed in a horizontal direction, which is not desirable.

The depth of the trench formed in the support layer 200 indicates a depth from the top surface of the support layer 200. That is, the depth of the trench formed in the support layer 200 may be measured with the top surface having the maximum level of the support layer 200 as a reference surface.

In the present embodiment, a depth D₃₁₂ of the first trench 312 may be expressed as the sum of the thickness of the base 130 and the depth D₂₀₀ of the trench of the support layer 200.

Since the positions, arrangements, sizes, shapes, and materials of the protrusion patterns 156 are the same as those of the above-described protrusion patterns 151, redundant description thereof will be omitted.

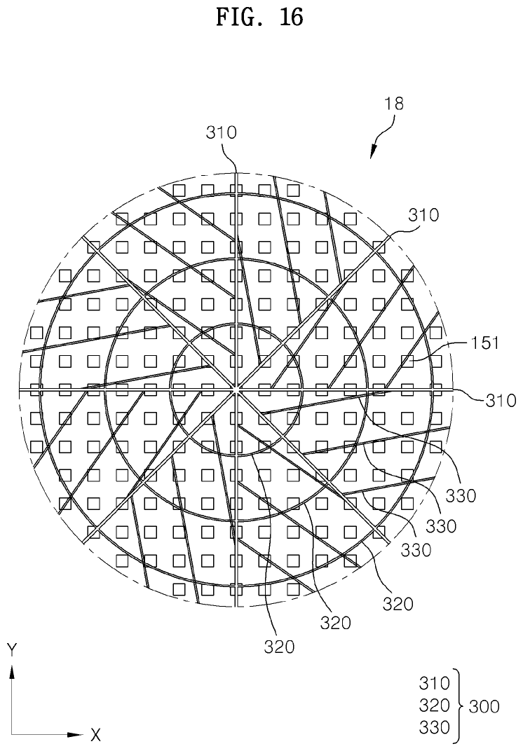

FIG. 15 is a cross-sectional view of a polishing pad 17 according to still another embodiment of the present invention, and is a cross-sectional view showing a position corresponding to that of FIG. 5.

Referring to FIG. 15, the polishing pad 17 of the present embodiment is different from the polishing pad 11 according to the embodiment of FIG. 5 in that a protrusion pattern 157 of a pattern layer 107 of the polishing pad 17 has partially inclined sidewalls. For example, the protrusion pattern 157 may have a shape in which a width increases from an upper side toward a lower side with reference to FIG. 15.

In an exemplary embodiment, the protrusion pattern 157 may have a first portion 157a formed in a substantially quadrilateral shape in plan view and having approximately vertical sidewalls and a second portion 157b having inclined or tapered sidewalls. The first portion 157a and the second portion 157b may be continuously integrally formed without a physical boundary. Further, the second portion 157b may be continuously integrally formed with the base 130 without a physical boundary. That is, the first portion 157a and the second portion 157b may be distinguished depending on the slope of the sidewall.

In this case, the polishing area and the circumferential length per unit area of the protrusion pattern 157 may be determined based on the size of the first portion 157a. This may be because the first portion 157a rather than the second portion 157b substantially contributes to polishing. For example, when the first portion 157a is formed in a square shape whose one side has a length of W, the second portion 157b is formed in a square shape whose one side has a length greater than W, four protrusion patterns 157 are positioned within an area of 1 mm², the polishing area of the protrusion pattern 157 may be expressed as n×W×W (n being the total number of the protrusion patterns) with respect to the total area of the polishing pad 17 in plan view. Further, the circumferential length of the protrusion pattern 157 per unit area may be expressed as 4×4×W mm/mm².

Further, a height H₁₅₇ₐ of the first portion 157a of the protrusion pattern 157 may affect the polishing characteristics and durability of the polishing pad 17. The minimum height of the first portion 157a may be within a range of about 0.01 mm or more and 1.0 mm or less, or about 0.01 mm or more and 0.5 mm or less, or about 0.01 mm or more and 0.3 mm or less. Further, although a height H_{157b} of the second portion 157b is not particularly limited, the sum (H₁₅₇ₐ+H_{157b}) of the heights of the first portion 157a and the second portion 157b is preferably within a range of about 1.5 mm or less. If the height (H₁₅₇ₐ+H_{157b}) of the protrusion pattern 157 exceeds 1.5 mm, the protrusion pattern 157 may be deformed during the polishing process.

Although not shown in the drawing, in another embodiment, the protrusion pattern 157 may further include a third portion (not shown) disposed between the second portion 157b and the base 130 and having a vertical sidewall. Alternatively, in another embodiment, the slope of the sidewall of the second portion 157b may change gradually or non-gradually, or may have a step, or may be arbitrary.

Since the positions, arrangements, and materials of the other protrusion patterns 157 are the same as those of the protrusion patterns 151, redundant description thereof will be omitted.

FIG. 16 shows a planar layout of a polishing pad 18 according to still another embodiment of the present invention.

Referring to FIG. 16, the polishing pad 18 according to the present embodiment is different from the polishing pad 11 according to the embodiment of FIG. 2 or the like in that it further includes a third trench 330.

The first trenches 310 have a shape extending substantially radially from the center of the circular polishing pad 18, and FIG. 16 illustrates a case in which eight first trenches 310 are formed. Further, the second trenches 320 are arranged concentrically with respect to the center of the circular polishing pad 18, and FIG. 16 illustrates a case in which three second trenches 320 are formed.

In an exemplary embodiment, the third trench 330 may have a structure in which it is connected to the first trench 310 and the second trench 320 while extending to intersect the first trench 310 and the second trench 320. Specifically, the plurality of third trenches 330 may extend in the direction intersecting the tangential direction of the rotation direction of the circular polishing pad 18. Although FIG. 16 illustrates the arrangement of the third trenches 330 in the case where the polishing pad 18 rotates in a counterclockwise direction in FIG. 16, the present invention is not limited thereto.

Further, when eight first trenches 310 are formed to partition the polishing pad 18 into eight fan-shaped regions having a central angle of approximately 45 degrees, the third trenches 330 may extend in substantially parallel to each other in any one of the fan-shaped regions. Further, the extending directions of the third trenches 330 positioned in two adjacent fan-shaped regions may have an angle difference of approximately 45 degrees. In other words, in the polishing pad 18, certain fan-shaped regions may be arranged in a circular shape.

The third trench 330 may induce slurry (not shown) to uniformly move or flow over the entire surface of the polishing pad 18 due to the centrifugal force generated by the rotation of the polishing pad 18. As a non-limiting example, the slurry (not shown) that has spread first by the radially extending first trenches 310 may move in the rotation direction by the second trenches 320 connected to the first trenches 310. Further, the slurry (not shown) may move in a diagonal direction by the third trenches 330 connected to the second trenches 320 (or the first trenches 310).

In some embodiments, the width of the first trench 310 may be greater than the width of the second trench 320, and the width of the second trench 320 may be greater than the width of the third trench 330. For example, the width of the first trench 310, the width of the second trench 320, and the width of the third trench 330 may be within a range of about 0.1 mm or more and less than 3.0 mm, or about 0.3 mm or more and 2.5 mm or less, or about 0.5 mm or more and 2.0 mm or less, or about 1.0 mm or more and 1.5 mm or less, and may be different from each other.

Although not illustrated in the drawing, in some embodiments, the maximum depth of the first trench 310 may be greater than the maximum depth of the second trench 320, and the maximum depth of the second trench 320 may be greater than the maximum depth of the third trench 330.

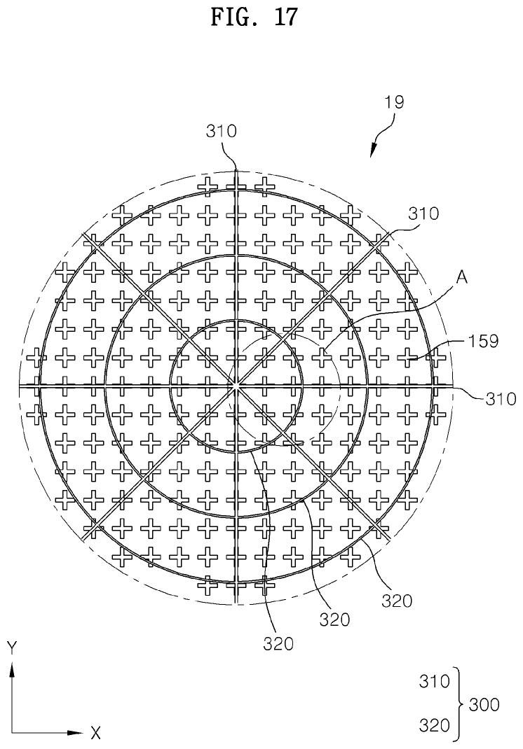

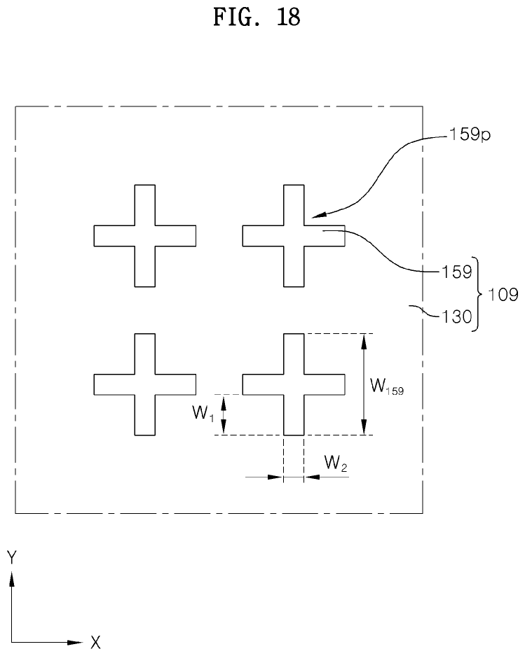

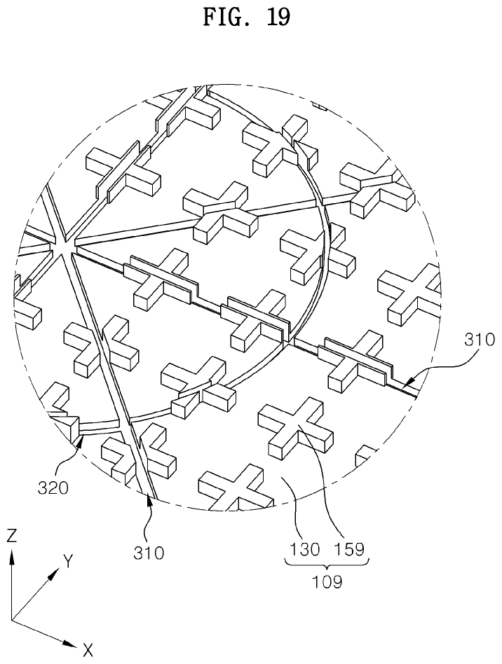

FIG. 17 shows a planar layout of a polishing pad 19 according to still another embodiment of the present invention. FIG. 18 is an enlarged plan view illustrating the arrangement of protrusion patterns 159 of FIG. 17. FIG. 19 is an enlarged perspective view of area A of FIG. 17.

Referring to FIGS. 17 to 19, the polishing pad 19 of the present embodiment is different from the polishing pad 11 according to the embodiment of FIG. 2 in that the protrusion pattern 159 of a pattern layer 109 of the polishing pad 19 has an approximately ‘+’ shape instead of a square shape in plan view.

The plurality of protrusion patterns 159 may be disposed on the base 130. As described above, the protrusion patterns 159 may be repeatedly arranged along at least two directions to form regular arrangement. For example, the protrusion patterns 159 may be repeatedly arranged at the same distance in the first direction X and the second direction Y in an approximately matrix shape. At least some of the first trenches 310 may extend in substantially the same direction as the arranging directions of the protrusion patterns 159. Further, as described above, the protrusion patterns 159 are partially removed so as not to overlap the trench 300.

The protrusion pattern 159 may have an approximately ‘+’ shape. Specifically, the protrusion pattern 159 may have an extension portion extending in the same direction as the arranging directions, e.g., in the first direction X and the second direction Y, with respect to an arbitrary point. Accordingly, the protrusion pattern 159 may have four recessed portions 159p at an upper left portion, an upper right portion, a lower right portion, and a lower left portion in plan view. In this case, a maximum width W₁₅₉ of the protrusion pattern 159 may be expressed as the length of two extension portions parallel to each other.

The size of the protrusion pattern 159 or the like may affect the removal rate, the non-uniformity, or the like of the polishing pad 19. In the case of the protrusion pattern 159 having a regular cross shape and satisfying 2×W₁+W₂=W₁₅₉ as in the present embodiment, the polishing area formed by any one of the protrusion patterns 159 may be expressed as W₁₅₉×W₁₅₉−4×W₁×W₁. Further, the circumferential length of any one of the protrusion patterns 159 may be expressed as 4×W₁₅₉.

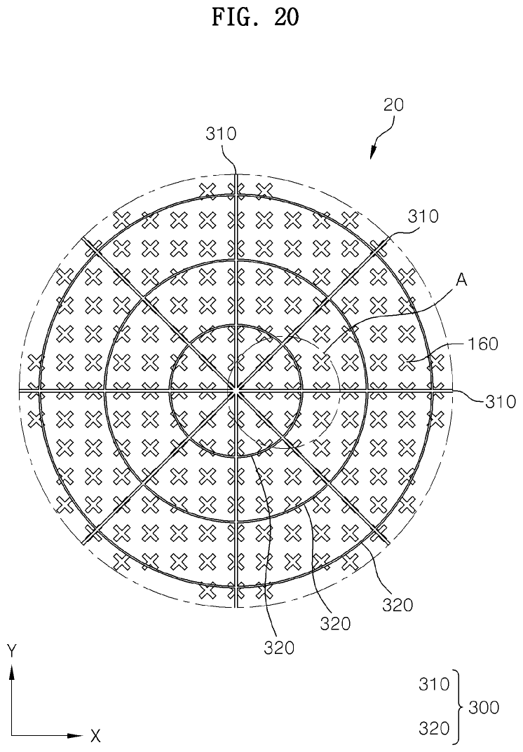

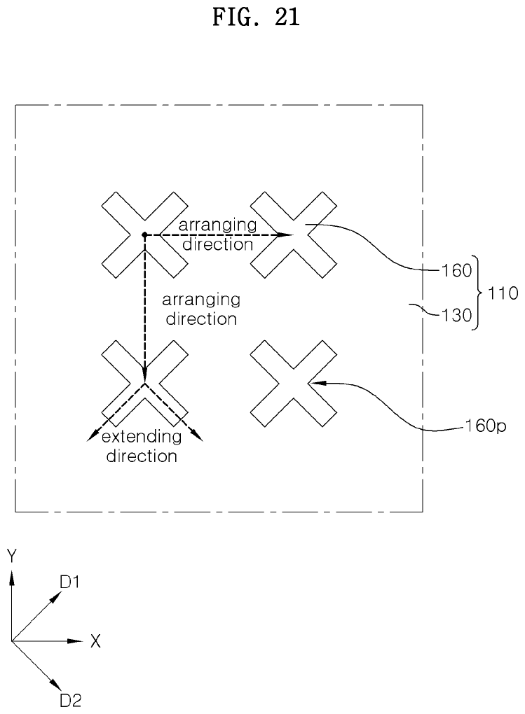

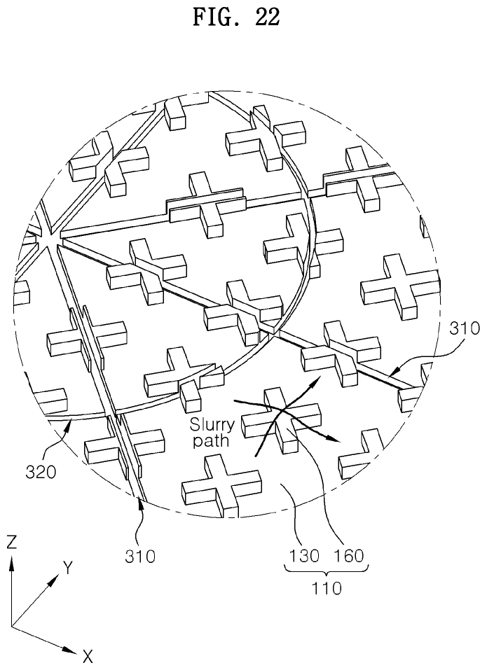

FIG. 20 shows a planar layout of a polishing pad 20 according to still another embodiment of the present invention. FIG. 21 is an enlarged plan view illustrating the arrangement of protrusion patterns 160 of FIG. 20. FIG. 22 is an enlarged perspective view of area A of FIG. 20.

Referring to FIGS. 20 to 22, the polishing pad 20 of the present embodiment is different from the polishing pad 19 according to the embodiment of FIG. 17 in that the protrusion pattern 160 of a pattern layer 110 of the polishing pad 20 has an approximately pivoted ‘+’ shape in plan view. That is, the protrusion pattern 160 may have an approximately ‘X’ shape in plan view. In this specification, the ‘X’ shape may be considered as the same shape as the ‘+’ shape except that it is pivoted.

The plurality of protrusion patterns 160 may be disposed on the base 130. As described above, the protrusion patterns 160 may be repeatedly arranged along at least two directions to form regular arrangement. For example, the protrusion patterns 160 may be repeatedly arranged at the same distance along the first direction X and the second direction Y in an approximately matrix shape. At least some of the first trench 310 may extend in substantially the same direction as the arranging directions of the protrusion patterns 160. Further, as described above, the protrusion pattern 160 is partially removed so as not to overlap the trench 300.

The protrusion pattern 160 may have an approximately ‘+’ shape, and specifically, may have extension portions extending in the first diagonal direction D1 and the second diagonal direction D2 different from the arranging directions (i.e., the first direction X and the second direction Y) with respect to an arbitrary point. Accordingly, the protrusion pattern 160 may have four recessed portions in plan view. The first diagonal direction D1 and the second diagonal direction D2 may be perpendicular to each other, and the first diagonal direction D1 may form an angle of about 40 degrees to 50 degrees, or about 45 degrees with the first direction X.

When the arranging directions (X and Y) of the protrusion patterns 160 are different from the extending directions (D1 and D2) of the extension portions of a certain protrusion pattern 160 as in the present embodiment, a structure in which slurry (not shown) flowing on the top surface of the polishing pad 20 flows in the opposite direction along the top surface of the protrusion pattern 160 may be formed. That is, the flow of the slurry is trapped and/or controlled by the recessed portions of the protrusion patterns 160 as well as the top surface of the base 130, so that the slurry forcibly flows toward the top surfaces of the protrusion patterns 160, which makes it possible to increase the utilization efficiency of the slurry.

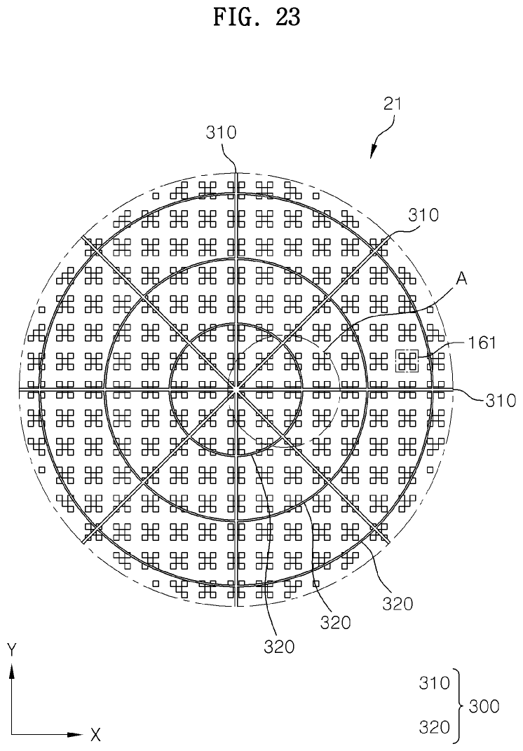

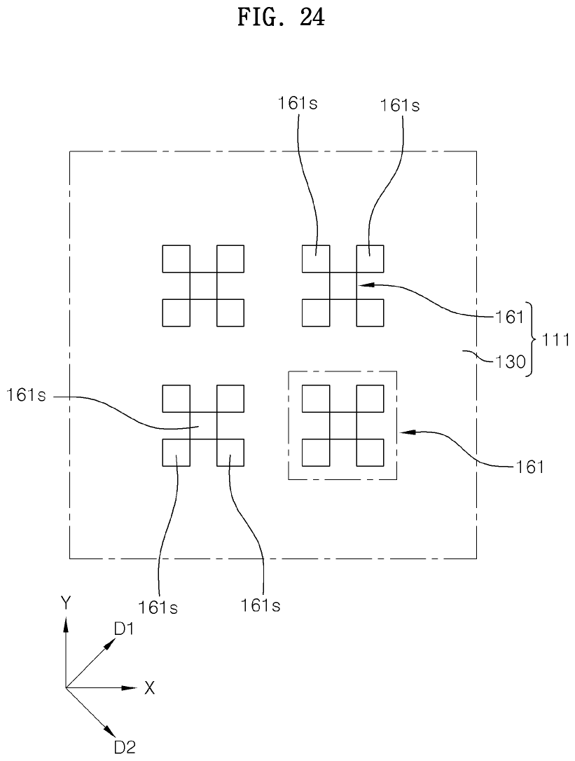

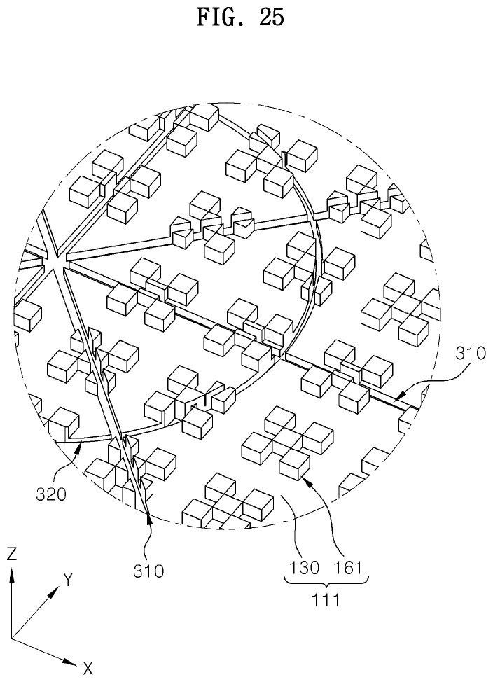

FIG. 23 shows a planar layout of a polishing pad 21 according to still another embodiment of the present invention. FIG. 24 is an enlarged plan view illustrating the arrangement of protrusion patterns 161 of FIG. 23. FIG. 25 is an enlarged perspective view of area A of FIG. 23.

Referring to FIGS. 23 to 25, the polishing pad 21 of the present embodiment is different from the polishing pad 20 according to the embodiment of FIG. 20 in that a certain protrusion pattern 161 of the polishing pad 21 includes a plurality of sub-patterns 161s.

The plurality of protrusion patterns 161 may be disposed on the base 130. As described above, the protrusion patterns 161 may be repeatedly arranged along at least two directions to form regular arrangement. For example, the protrusion patterns 161 may be repeatedly arranged at the same distance along the first direction X and the second direction Y in an approximately matrix shape. At least some of the first trenches 310 may extend in substantially the same direction as the arranging directions of the protrusion patterns 161. Further, as described above, the protrusion pattern 161 is partially removed so as not to overlap the trench 300. The protrusion pattern 161 has an approximately ‘X’ shape, and may include the plurality of sub-patterns 161s. The sub-patterns 161s may have the same shape, and the sub-patterns 161s forming one protrusion pattern 161 may be approximately regularly arranged. The sub-patterns 161s may have substantially the same height.

In an exemplary embodiment, the sub-patterns 161s may have a square shape in plan view. Further, the sub-patterns 161s may be at least partially in contact with each other. The recessed portion of the protrusion pattern 161 may be formed between the adjacent sub-patterns 161s.

Specifically, a certain protrusion pattern 161 may be formed of five sub-patterns 161s including a certain sub-pattern 161s, two sub-patterns 161s located on one side and the other side of the first diagonal direction D1 with respect to the certain sub-pattern 161s, and two sub-patterns 161s located on one side and the other side of the second diagonal direction D2 with respect to the certain sub-pattern 161s, the first diagonal direction D1 and the second diagonal direction D2 being different from the arranging directions (i.e., the first direction X and the second direction Y) of the protrusion pattern 161, but the present invention is not limited thereto.

When the protrusion pattern 161 is formed of the sub-patterns 161s, and the arranging directions D1 and D2 between the sub-patterns 161s and the arranging directions X and Y between the protrusion patterns 161 are different as in the present embodiment, the utilization efficiency of the slurry may be increased.

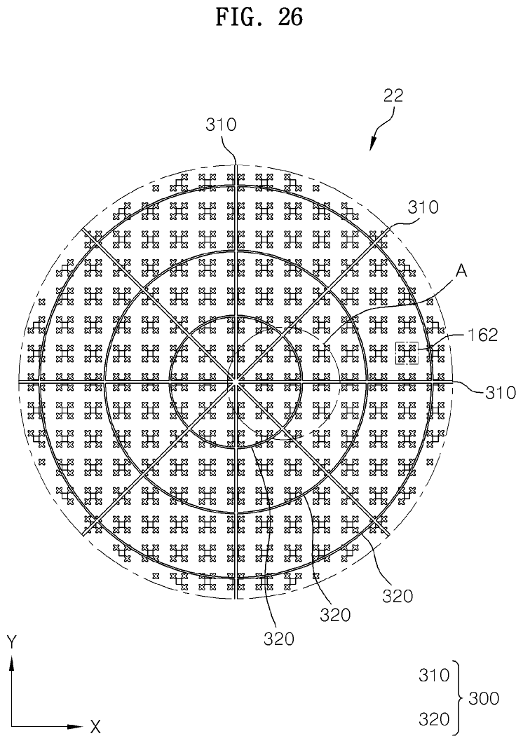

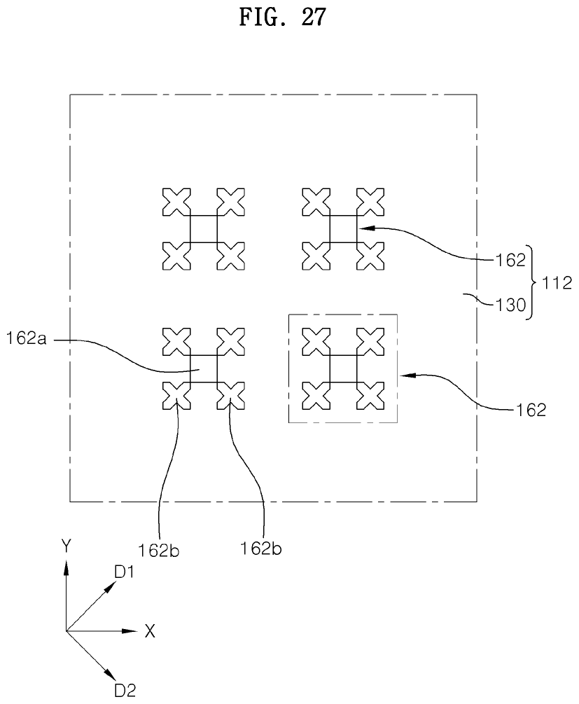

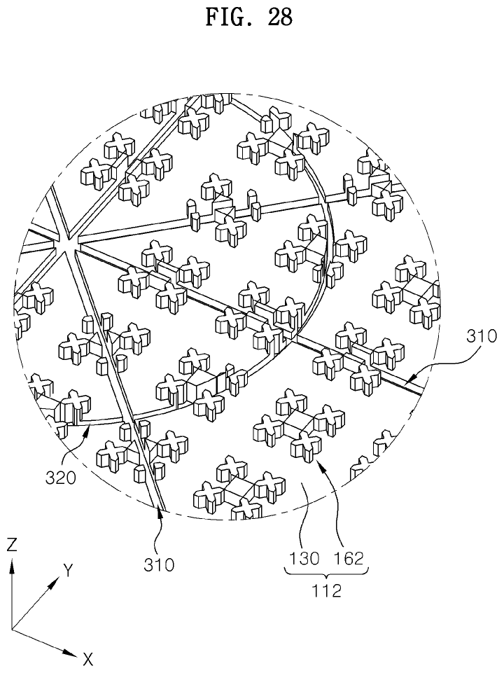

FIG. 26 shows a planar layout of a polishing pad 22 according to still another embodiment of the present invention. FIG. 27 is an enlarged plan view illustrating the arrangement of protrusion patterns 162 of FIG. 26. FIG. 28 is an enlarged perspective view of area A of FIG. 26.

Referring to FIGS. 26 to 28, the polishing pad 22 of the present embodiment is different from the polishing pad 21 according to the embodiment of FIG. 23 in that a certain protrusion pattern 162 of the polishing pad 22 includes a plurality of sub-patterns 162a and 162b, and at least some of the sub-patterns 162a and 162b have different shapes.

The plurality of protrusion patterns 162 may be disposed on the base 130. As described above, the protrusion patterns 162 may be repeatedly arranged along at least two directions to form regular arrangement. For example, the protrusion patterns 162 may be repeatedly arranged at the same distance along the first direction X and the second direction Y in an approximately matrix shape. At least some of the first trenches 310 may extend in substantially the same direction as the arranging directions of the protrusion patterns 162. Further, as described above, the protrusion pattern 162 is partially removed so as not to overlap the trench 300.

The protrusion pattern 162 may have an approximately ‘X’ shape, and may be formed of the plurality of sub-patterns including the first sub-pattern 162a and the second sub-patterns 162b. The first sub-pattern 162a and the second sub-pattern 162b may have different shapes, and the sub-patterns forming one protrusion pattern 162 may be approximately regularly arranged. Further, the heights of the first sub-pattern 162a and the second sub-pattern 162b may be substantially the same. Further, the first sub-pattern 162a and the second sub-pattern 162b may be at least partially in contact with each other.

In an exemplary embodiment, in plan view, the first sub-pattern 162a may have an approximately square shape, and the second sub-pattern 162b may have an approximately ‘X’ shape. Specifically, the protrusion pattern 162 may be formed of five sub-patterns including the first sub-pattern 162a, two sub-patterns 162b located on one side and the other side of the first diagonal direction D1 with respect to the first sub-pattern 162a, and two sub-patterns 162b located on one side and the other side of the second diagonal direction D2 with respect to the first sub-pattern 162a, the first diagonal direction D1 and the second diagonal direction D2 being different from the arranging directions (i.e., the first direction X and the second direction Y) of the protrusion patterns 162, but the present invention is not limited thereto.

As in the present embodiment, the protrusion pattern 162 may be formed of different shaped sub-patterns including the first sub-pattern 162a and the second sub-patterns 162b, and the shape of at least some of the sub-patterns may be controlled to control the polishing area and the circumferential length formed by the protrusion pattern 162.

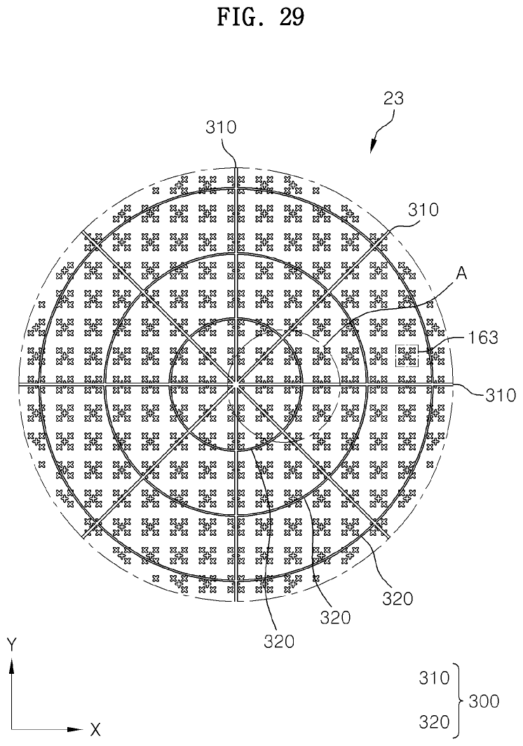

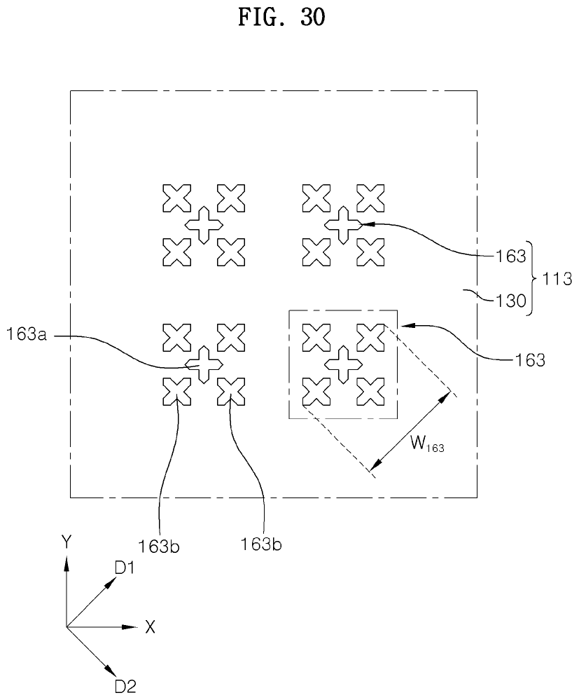

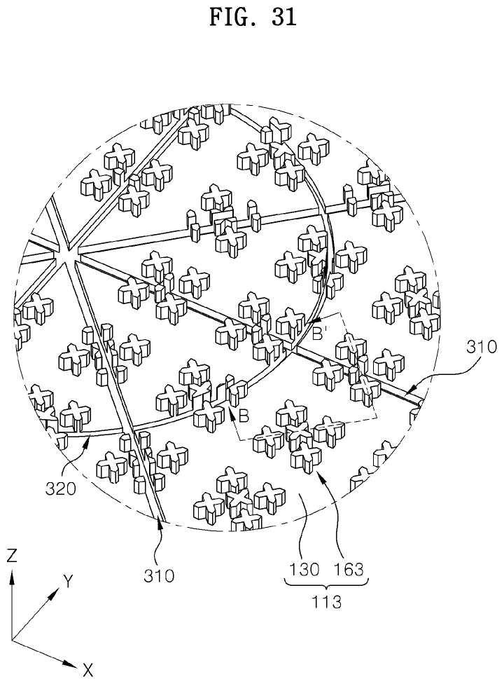

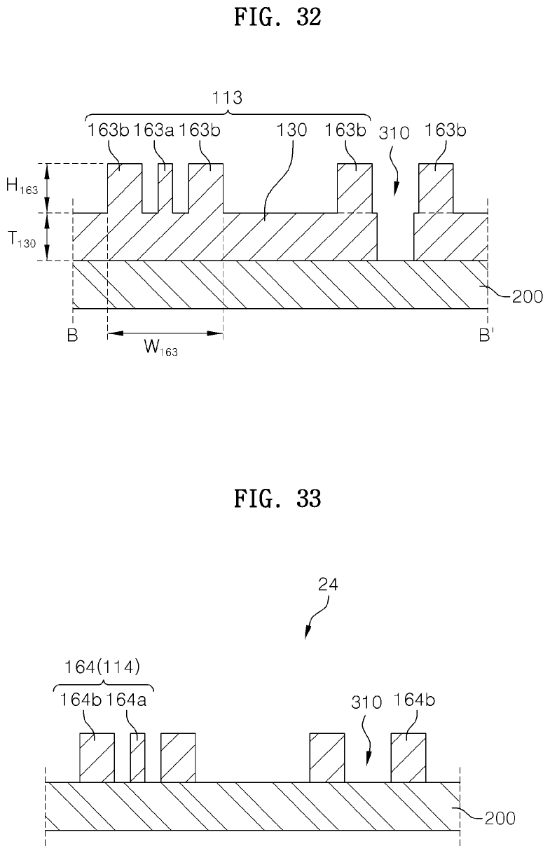

FIG. 29 shows a planar layout of a polishing pad 23 according to still another embodiment of the present invention. FIG. 30 is an enlarged plan view illustrating the arrangement of protrusion patterns 163 of FIG. 29. FIG. 31 is an enlarged perspective view of area A of FIG. 29. FIG. 32 is a cross-sectional view taken along line B-B′ of FIG. 31 to illustrate two protrusion patterns 163 and the first trench 310.

Referring to FIGS. 29 to 32, the polishing pad 23 of the present embodiment is different from the polishing pad 22 according to the embodiment of FIG. 26 or the like in that a certain protrusion pattern 163 of the polishing pad 23 includes a plurality of sub-patterns 163a and 163b, and the sub-patterns 163a and 163b are spaced from each other without being in contact with each other.

The plurality of protrusion patterns 163 may be disposed on the base 130. As described above, the protrusion patterns 163 may be repeatedly arranged along at least two directions to form regular arrangement. For example, the protrusion patterns 163 may be repeatedly arranged at the same distance along the first direction X and the second direction Y in an approximately matrix shape. At least some of the first trenches 310 may extend in substantially the same direction as the arranging directions of the protrusion patterns 163. Further, as described above, the protrusion pattern 163 is partially removed so as not to overlap the trench 300.

The protrusion pattern 163 may have an approximately ‘X’ shape, and may be formed of the plurality of sub-patterns including the first sub-pattern 163a and the second sub-patterns 163b. The first sub-pattern 163a and the second sub-pattern 163b may have the same shape, and the sub-patterns forming one protrusion pattern 163 may be approximately regularly arranged. The heights of the first sub-pattern 163a and the second sub-pattern 163b may be substantially the same.

In an exemplary embodiment, in plan view, both the first sub-pattern 163a and the second sub-pattern 163b have an approximately ‘+’ shape and the second sub-pattern 163b may be pivoted compared to the first sub-pattern 163a to have an approximately ‘X’ shape. Specifically, the protrusion pattern 163 may be formed of five sub-patterns including the first sub-pattern 163a, two sub-patterns 163b located on one side and the other side of the first diagonal direction D1 with respect to the first sub-pattern 163a, and two second sub-patterns 163b located on one side and the other side of the second diagonal direction D2 with respect to the first sub-pattern 163a, the first diagonal direction D1 and the second diagonal direction D2 being different from the arranging directions (i.e., the first direction X and the second direction Y) of the protrusion pattern 163, but the present invention is not limited thereto.

As described above, a height H₁₆₃, e.g., the minimum height, of the protrusion pattern 163 may be within a range of about 0.01 mm or more and 1.5 mm or less, or about 0.01 mm or more and 1.0 mm or less, or about 0.01 mm or more and 0.5 mm or less, or about 0.01 mm or more and 0.3 mm or less. Further, the thickness T₁₃₀, e.g., the maximum thickness, of the base 130 may be within a range of about 0.01 mm to 3.0 mm, or about 0.1 mm to 2.5 mm, or about 0.5 mm to 2.0 mm, or about 1.0 mm to 1.5 mm.

In some embodiments, the maximum depth T₁₃₀ of the first trench 310 may be greater than the height H₁₆₃ of the protrusion pattern 163. In an exemplary embodiment in which the trench is formed in the pattern layer 113, it may be preferable that the maximum depth T₁₃₀ of the first trench 310 is greater than the height H₁₆₃ of the protrusion pattern 163 in terms of the fluidity on the pattern layer 113 and the followability to the polishing target substrate.

The protrusion pattern 163 of the polishing pad 23 according to the present embodiment may include the plurality of sub-patterns 163a and 163b having the same shape or different shapes unlike the drawing, and they may be spaced apart from each other by a predetermined distance. The protrusion pattern 163 may have an approximately ‘+’ or ‘X’ shape as a whole to form a structure in which the slurry forcibly flows in the opposite direction along the top surface of the protrusion pattern 163, and large particles or impurities in the slurry may pass through the space between the sub-patterns 163a and 163b. That is, a material that causes damage to the polishing target substrate is made to pass through the space between the sub-patterns 163a and 163b without flowing to the top surface of the protrusion pattern 163, so that it is possible to further improve the polishing characteristics.

FIG. 33 is a cross-sectional view of a polishing pad 24 according to still another embodiment of the present invention, and is a cross-sectional view showing a position corresponding to that of FIG. 32.

Referring to FIG. 33, the polishing pad 24 according to the present embodiment is different from the polishing pad 23 according to the embodiment of FIG. 32 or the like in that it includes the support layer 200 and a pattern layer 114 disposed on the support layer 200, and the pattern layer 114 includes protrusion patterns 164 without having a separate base.

In an exemplary embodiment, the plurality of protrusion patterns 164 including first sub-patterns 164a and second sub-patterns 164b may be directly disposed on the support layer 200, and the plurality of protrusion patterns 164 may be spaced apart from each other. Accordingly, the trench including the first trench 310 may have a depth corresponding to the height of the protrusion pattern 164.

In another embodiment, unlike the drawing, a trench may be formed on a part of the top surface of the support layer 200.

Since the positions, arrangements, sizes, shapes, and materials of the sub-patterns 164a and 164b and the protrusion patterns 164 are the same as those of the protrusion patterns 163, redundant description thereof will be omitted.

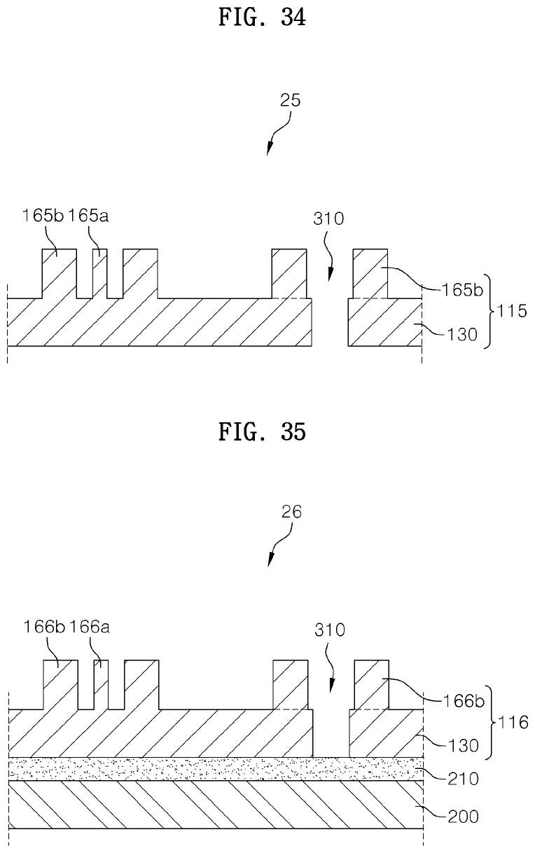

FIG. 34 is a cross-sectional view of a polishing pad 25 according to still another embodiment of the present invention, and is a cross-sectional view showing a position corresponding to that of FIG. 32.

Referring to FIG. 34, the polishing pad 25 according to the present embodiment is different from the polishing pad 23 according to the embodiment of FIG. 32 or the like in that it includes a pattern layer 115 including the base 130 and sub-patterns 165a and 165b, but does not have a separate support layer. In this case, the pattern layer 115 may be directly disposed on a polishing platen (not shown).

Since the positions, arrangements, sizes, shapes, and materials of the sub-patterns 165a and 165b and the protrusion patterns are the same as those of the above-described protrusion patterns 163, redundant description thereof will be omitted.

FIG. 35 is a cross-sectional view of a polishing pad 26 according to still another embodiment of the present invention, and is a cross-sectional view showing a position corresponding to that of FIG. 32.

Referring to FIG. 35, the polishing pad 26 according to the present embodiment is different from the polishing pad 23 according to the embodiment of FIG. 32 or the like in that it further includes the bonding layer 210 interposed between the support layer 200 and a pattern layer 116.

The bonding layer 210 may be interposed between the support layer 200 and the pattern layer 116 to couple them. The top surface of the bonding layer 210 may be partially exposed by the trench including the first trench 310 and the second trench (not shown). Although not shown in the drawing, in another embodiment, a trench may be formed on a part of one surface (the top surface in FIG. 35) of the bonding layer 210. Alternatively, the bonding layer 210 disposed at a position overlapping the first trench 310 may be completely removed to form a trench.

Since the positions, arrangements, sizes, shapes, and materials of sub-patterns 166a and 166b and the protrusion patterns are the same as those of the above-described protrusion patterns 163, redundant description thereof will be omitted.

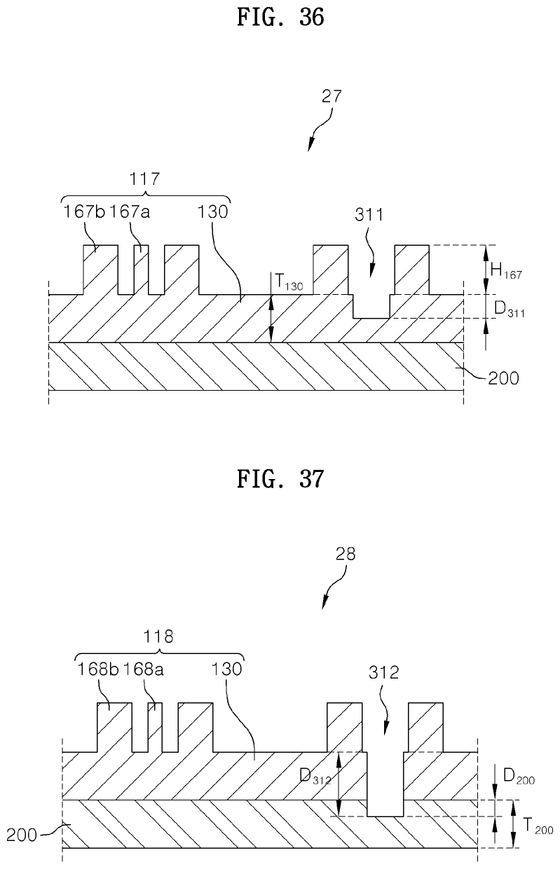

FIG. 36 is a cross-sectional view of a polishing pad 27 according to still another embodiment of the present invention, and is a cross-sectional view showing a position corresponding to that of FIG. 32.

Referring to FIG. 36, the polishing pad 27 according to the present embodiment is different from the polishing pad 23 according to the embodiment of FIG. 32 or the like in that it has the trench including the first trench 311 and the second trench (not shown), and the trench is partially recessed without completely penetrating the base 130 of the pattern layer 117.

As described above, a height H₁₆₇, e.g., the minimum height, of sub-patterns 167a and 167b may be within a range of about 0.01 mm or more and 1.5 mm or less, or about 0.01 mm or more and 1.0 mm or less, or about 0.01 mm or more and 0.5 mm or less, or about 0.01 mm or more than 0.3 mm or less. Further, the thickness T₁₃₀, e.g., the maximum thickness, of the base 130 may be in the range of about 0.01 mm to 3.0 mm, or about 0.1 mm to 2.5 mm, or about 0.5 mm to 2.0 mm, or about 1.0 mm to 1.5 mm.

In this case, the depth D₃₁₁, e.g., the maximum depth, of the trench may be smaller than the thickness T₁₃₀ of the base 130. Unlike the drawing, the depth Dan of the trench may be greater than the height H₁₆₇ of the protrusion pattern.

Since the positions, arrangements, sizes, shapes, and materials of the sub-patterns 167a and 167b and the protrusion patterns are the same as those of the above-described protrusion patterns 163, redundant description thereof will be omitted.

FIG. 37 is a cross-sectional view of a polishing pad 28 according to still another embodiment of the present invention, and is a cross-sectional view showing a position corresponding to that of FIG. 32.

Referring to FIG. 37, the polishing pad 28 according to the present embodiment is different from the polishing pad 23 according to the embodiment of FIG. 32 or the like in that it has the trench including the first trench 312 and the second trench (not shown), and the trench reaches the support layer 200 as well as the pattern layer 118.

In an exemplary embodiment, a trench may be formed on a part of one surface (the upper surface in FIG. 37) of the support layer 200. That is, the trench of the support layer 200 may overlap and be connected to the trench of the pattern layer 118 to form one trench.

In this case, the maximum depth D₂₀₀ of the trench of the support layer 200 may have a predetermined relationship with the maximum thickness T₂₀₀ of the support layer 200. For example, the maximum depth D₂₀₀ of the trench in the support layer 200 may be within a range of about 50% or less, or about 40% or less, or about 30% or less, or about 20% or less of the maximum thickness T₂₀₀ of the support layer 200. If the trench is formed in a range exceeding 50% of the maximum thickness T₂₀₀ of the support layer 200, the durability of the support layer 200 may be reduced, and the overall lifetime and durability of the polishing pad 16 may be shortened.

In the present embodiment, the depth D₃₁₂ of the first trench 312 may be expressed as the sum of the thickness of the base 130 and the depth Do of the trench of the support layer 200.

Since the positions, arrangements, sizes, shapes, and materials of sub-patterns 168a and 168b and the protrusion patterns are the same as those of the above-described protrusion patterns 163, redundant description thereof will be omitted.

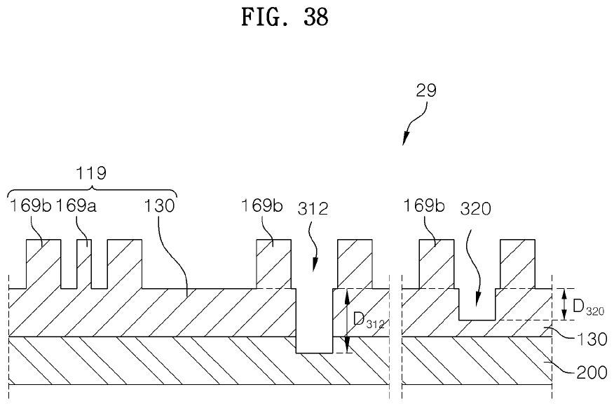

FIG. 38 is a cross-sectional view of a polishing pad 29 according to still another embodiment of the present invention, and is a cross-sectional view showing a position corresponding to that of FIG. 32.

Referring to FIG. 38, the polishing pad 29 according to the present embodiment is different from the polishing pad 28 according to the embodiment of FIG. 37 in that it includes the first trench 312 and the second trench 320, and the maximum depth D₃₁₂ of the first trench 312 is greater than a maximum depth D₃₂₀ of the second trench 320.

In an exemplary embodiment, the plurality of first trenches 312 extending in a radial direction from the center of the circular polishing pad 29 in plan view may be formed over the base 130 of the pattern layer 119 and a part of the support layer 200 to have the first depth D31. Accordingly, the first trench 312 may partially expose the support layer 200.

On the contrary, the plurality of second trenches 320 arranged concentrically with respect to the center of the circular polishing pad 29 in plan view may be partially recessed without completely penetrating the base 130 of the pattern layer 119 to have the second depth D₃₂₀. Accordingly, the second trench 320 may not expose the support layer 200.

Although not shown in the drawing, the width of the first trench 312 may be greater than the width of the second trench 320.

Since the positions, arrangements, sizes, shapes, and materials of sub-patterns 169a and 169b and the protrusion patterns are the same as those of the above-described protrusion patterns 163, redundant description thereof will be omitted.

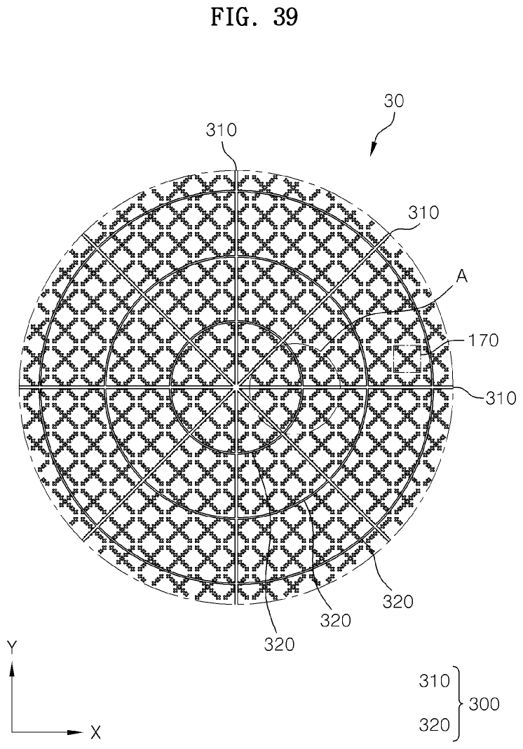

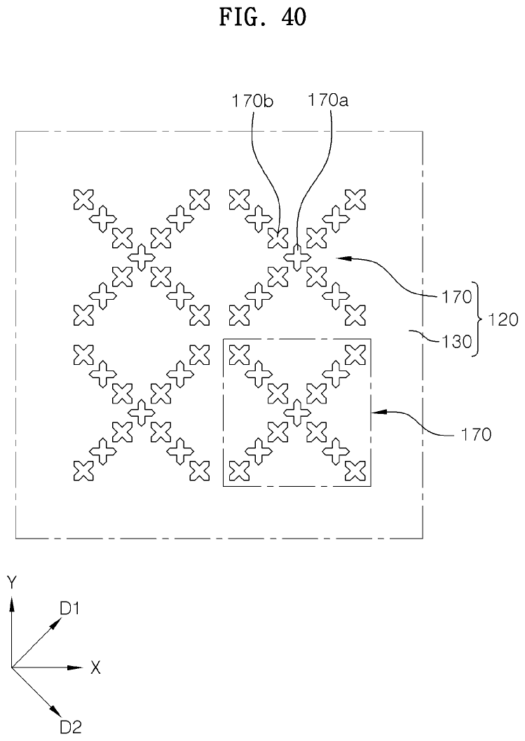

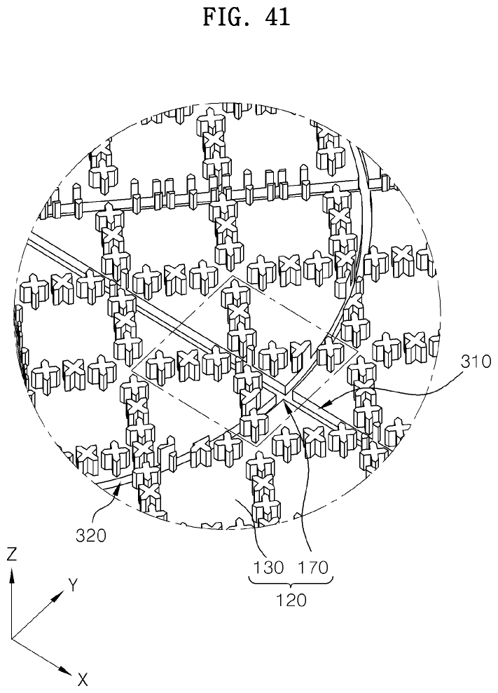

FIG. 39 shows a planar layout of a polishing pad 30 according to still another embodiment of the present invention. FIG. 40 is an enlarged plan view illustrating the arrangement of protrusion patterns 170 of FIG. 39. FIG. 41 is an enlarged perspective view of area A of FIG. 39.

Referring to FIGS. 39 to 41, the polishing pad 30 of the present embodiment is different from the polishing pad 23 according to the embodiment of FIG. 29 in that a certain protrusion pattern 170 of the polishing pad 30 includes a plurality of sub-patterns 170a and 170b, and the plurality of first sub-patterns 170a and second sub-patterns 170b are alternately and regularly arranged.

The plurality of protrusion patterns 170 may be disposed on the base 130. As described above, the protrusion patterns 170 may be repeatedly arranged along at least two directions to form regular arrangement. For example, the protrusion patterns 170 may be repeatedly arranged at the same distance along the first direction X and the second direction Y in an approximately matrix shape. At least some of the first trenches 310 may extend in substantially the same direction as the arranging directions of the protrusion patterns 170. Further, as described above, the protrusion pattern 170 is partially removed so as not to overlap the trench 300.

The protrusion pattern 170 may have an approximately ‘X’ shape, and may be formed of the plurality of sub-patterns including the first sub-patterns 170a and the second sub-patterns 170b. The first sub-pattern 170a and the second sub-pattern 170b may have the same shape, and the sub-patterns forming one protrusion pattern 170 may be approximately regularly arranged. The heights of the first sub-pattern 170a and the second sub-pattern 170b may be substantially the same.

In an exemplary embodiment, both the first sub-pattern 170a and the second sub-pattern 170b may have an approximately ‘+’ shape in plan view, and the second sub-pattern 170b may be pivoted compared to the first sub-pattern 170a to have an approximately ‘X’ shape.

Specifically, with respect to the first sub-pattern 170a, the first sub-patterns 170a and the second sub-patterns 170b may be disposed on one side and the other side of the first diagonal direction D1 and one side and the other side of the second diagonal direction D2 which are different from the arranging directions (i.e., the first direction X and the second direction Y) of the protrusion patterns 170. Further, the protrusion pattern 170 may be formed of thirteen sub-patterns by alternately arranging the first sub-patterns 170a and the second sub-patterns 170b, but the present invention is not limited thereto. That is, the arranging directions of the sub-patterns 170a and 170b may be the first diagonal direction D1 and the second diagonal direction D2.

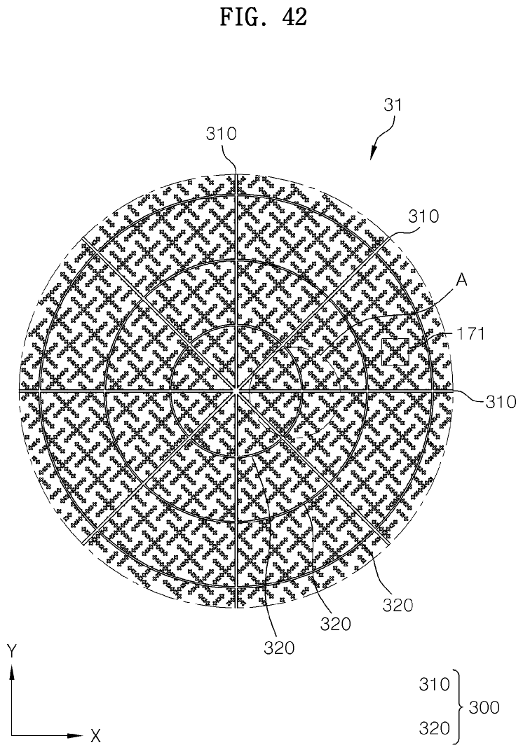

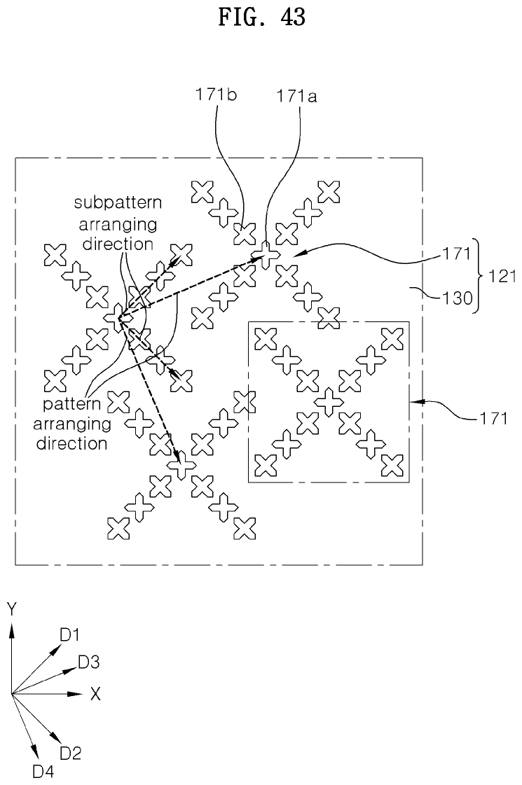

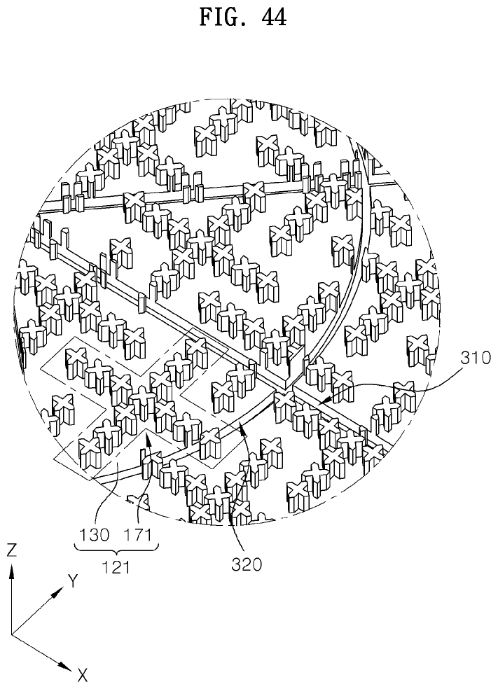

FIG. 42 shows a planar layout of a polishing pad 31 according to still another embodiment of the present invention. FIG. 43 is an enlarged plan view illustrating the arrangement of protrusion patterns 171 of FIG. 42. FIG. 44 is an enlarged perspective view of area A of FIG. 42.

Referring to FIGS. 42 to 44, the polishing pad 31 of the present embodiment is different from the polishing pad 30 according to the embodiment of FIG. 39 or the like in that the arranging directions of the protrusion patterns 171 of the polishing pad 31 intersect the extending directions of the first trenches 310, and the arranging directions of the protrusion patterns 171 intersect the arranging directions of the sub-patterns 171a and 171b.

The plurality of protrusion patterns 171 may be disposed on the base 130. As described above, the protrusion patterns 171 may be repeatedly arranged along at least two directions to form regular arrangement.

In an exemplary embodiment, the protrusion patterns 171 may be repeatedly arranged at the same distance along the third diagonal direction D3 and the fourth diagonal direction D4 intersecting the first direction X and the second direction Y. The third diagonal direction D3 and the fourth diagonal direction D4 may be perpendicular to each other, and the third diagonal direction D3 may form an angle of about 20 to 40 degrees, or about 25 to 35 degrees, or about 30 degrees with the first direction X.

Further, at least some or all of the first trenches 310 may extend in the directions intersecting the arranging directions (i.e., the third diagonal direction D3 and the fourth diagonal direction D4) of the protrusion patterns 171. As described above, the protrusion pattern 171 is partially removed so as not to overlap the trench 300.

The protrusion pattern 171 may have an approximately ‘X’ shape, and may be formed of the plurality of sub-patterns including the first sub-patterns 171a and the second sub-patterns 171b. In plan view, both the first sub-pattern 171a and the second sub-pattern 171b may have an approximately ‘+’ shape, and the second sub-pattern 171b may be pivoted compared to the first sub-pattern 171a to have an approximately ‘X’ shape. Further, with respect to the first sub-pattern 171a, the first sub-patterns 171a and the second sub-patterns 171b may be disposed on one side and the other side of the first diagonal direction D1 and on one side and the other side of the second diagonal direction D2. The protrusion pattern 171 may be formed of thirteen sub-patterns by alternately arranging the first sub-patterns 171a and the second sub-patterns 171b. That is, the arranging directions of the sub-patterns 171a and 171b may be the first diagonal direction D1 and the second diagonal direction D2, and the arranging directions of the sub-patterns 171a and 171b may intersect the extending directions (the first direction X and the second direction Y) of the first trenches 310 and the arranging directions (the third diagonal direction D3 and the fourth diagonal direction D4) of the protrusion patterns 171.

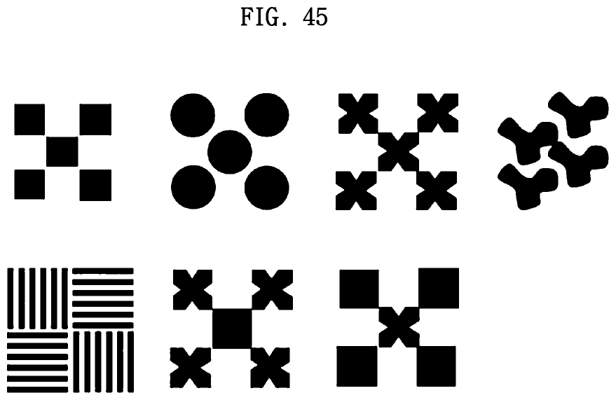

FIG. 45 is a schematic diagram of protrusion patterns and/or sub-patterns according to another embodiment of the present invention, and illustrates seven pattern arrangements and shapes.

Referring to FIG. 45, in some other embodiments, the protrusion pattern may be formed of quadrilateral sub-patterns spaced apart from each other, or circular sub-patterns spaced apart from each other, or approximately ‘X’-shaped sub-patterns, or sub-patterns formed in an arbitrary shape and having curved side surfaces, or linearly extending sub-patterns, or sub-patterns having a quadrilateral shape and an ‘X’ shape in plan view.

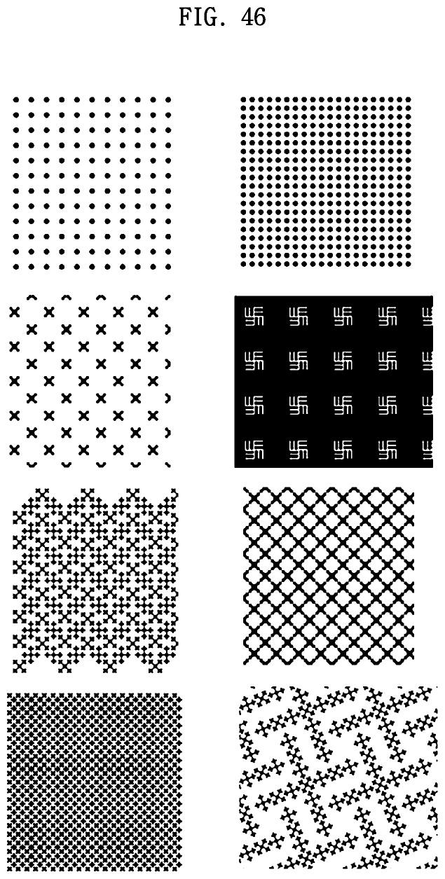

FIG. 46 is a schematic diagram of protrusion patterns and/or sub-patterns according to still another embodiment of the present invention, and illustrates eight pattern arrangements and shapes.

Referring to FIG. 46, in some other embodiments, in plan view, circular protrusion patterns may be regularly arranged in a matrix shape, or protrusion patterns having an ‘X’ or ‘+’ shape may be regularly arranged, or protrusion patterns may have an ‘X’ or ‘+’ shape having protrusions. Further, the protrusion patterns may be arranged in a diagonal direction other than the horizontal direction (e.g., the first direction X) and the vertical direction (e.g., the second direction Y) in a matrix shape.

Hereinafter, a method of preparing a polishing pad according to one embodiment of the present invention will be described.

The method of preparing a polishing pad according to the present embodiment includes disposing a pattern layer having a protrusion pattern on a support layer, and forming a trench in at least the pattern layer.

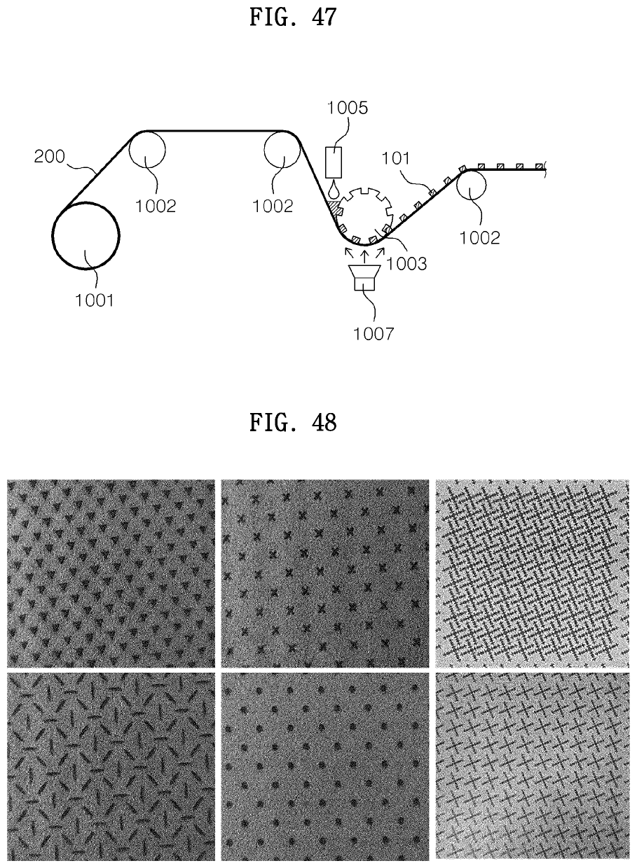

FIG. 47 is a process schematic diagram illustrating the method of preparing a polishing pad according to one embodiment of the present invention, specifically, the step of disposing the pattern layer 101 on the support layer 200.

Referring to FIG. 47, the support layer 200 may be wound around an unwinding roll 1001 in the form of a film. The support layer 200 wound around the unwinding roll 1001 may be unwound and transferred by a plurality of transfer rolls 1002.

A pattern composition nozzle 1005 may provide a composition for forming the pattern layer 101 onto one surface of the support layer 200, and an intended protrusion pattern may be processed by a patterning mold 1003 and cured by a curing unit 1007 to form the pattern layer 101. Although FIG. 47 illustrates only the protrusion pattern as the pattern layer 101, the present invention is not limited thereto, and the pattern layer 101 may include a base and the protrusion pattern. The patterning mold 1003 may include a soft mold or a hard mold. Further, the curing unit 1007 may include a photocuring device and/or a thermosetting device.

The film in which the pattern layer 101 is formed on the support layer 200 may be transferred by the transfer roll 1002 and subjected to post-treatment. In another embodiment, the film in which the pattern layer 101 is formed on the support layer 200 may be wound by a winding roll (not shown) or the like.

That is, in accordance with the preparing method according to the present embodiment, the film including the support layer 200 and the pattern layer 101 may be easily formed by a roll-to-roll process.

Although not shown in the drawing, after the pattern layer 101 is disposed on the support layer 200, the step of forming trenches may be executed. The trench may include radially extending first trenches, concentrically arranged second trenches, and/or diagonally extending third trenches. The step of forming the trenches may include laser processing, laser trimming, or the like.

Further, in this step, at least some of the protrusion patterns of the pattern layer 101 may be partially removed to prevent overlapping of the trenches and the protrusion patterns. The trenches may be formed to partially recess the pattern layer 101 to prevent exposure of the support layer 200, or may be formed to completely penetrate the pattern layer 101 to partially expose the support layer 200, or may be formed to completely penetrate the pattern layer 101 and partially recess the support layer 200.

Then, the step of processing the film including the support layer 200 and the pattern layer 101 where the trenches are formed in a circular shape may be further executed.

Hereinafter, the present invention will be described in more detail with reference to specific preparation examples, a comparative example and test examples.

### Preparation Example 1: Preparation of Protrusion Patterns of Various Shapes

A polishing pad including protrusion patterns having various shapes, arrangements, and sizes were prepared by the above-described method. Polyurethane was used for both the support layer and the pattern layer. The images thereof are shown in FIG. 48. Referring to FIG. 48, it is clear that protrusions patterns having desired shapes, arrangements, and sizes may be prepared.

### Preparation Example 2: Preparation of Protrusion Pattern Having ‘+’ Shape

A polishing pad including protrusion patterns having the same shape as that illustrated in the right images of FIG. 48 and FIG. 42 was prepared. Polyurethane was used for both the support layer and the pattern layer. Further, polishing pads having various polishing areas and circumferential lengths per unit area were prepared while varying the arrangement density and maintaining the sizes of the protrusion patterns and the sub-patterns. The width of the extension portion of one sub-pattern having a ‘+’ shape was approximately 20 μm, and one protrusion pattern was formed of thirteen sub-patterns.

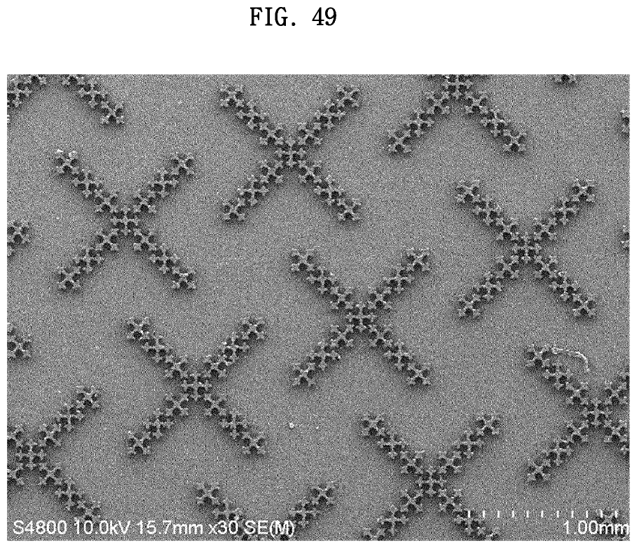

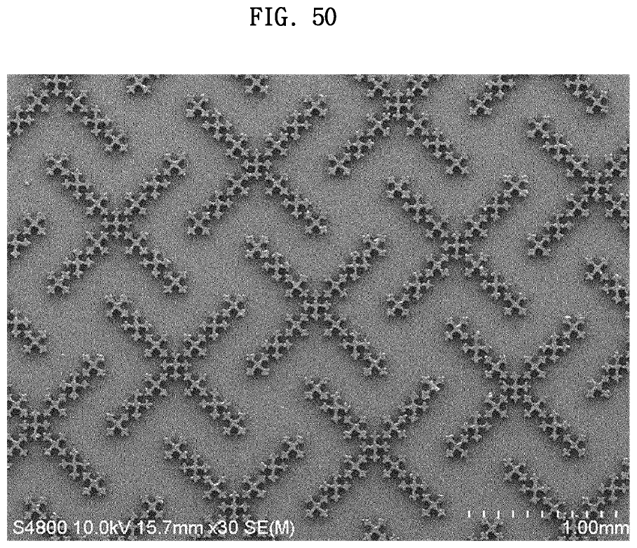

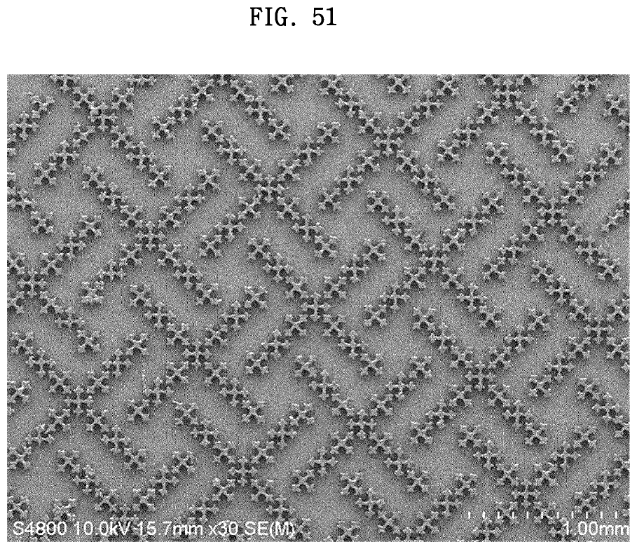

At this time, the polishing areas with respect to the total area were 2.5±0.5%, 5.0±0.5%, 12±0.5%, 15±0.5%, 20±0.5%, 30±0.5%, and 50±0.5%. Among them, the microscopic images of the polishing pads having the polishing areas of 5.0±0.5%, 15±0.5%, and 20±0.5% are shown in FIGS. 49 to 51, respectively.

Referring to FIGS. 49 to 51, it is clear that the polishing pads having desired shapes, arrangements, and sizes and including protrusion patterns having designed polishing areas and circumferential lengths may be prepared.

### Preparation Example 3: Preparation of Circular Protrusion Pattern

A polishing pad including protrusion patterns having the same shape as that illustrated in the lower center image of FIG. 48 was prepared. The polishing area with respect to the total area was set to about 10±0.5%.

### Comparative Example: Conventional CMP Polishing Pad

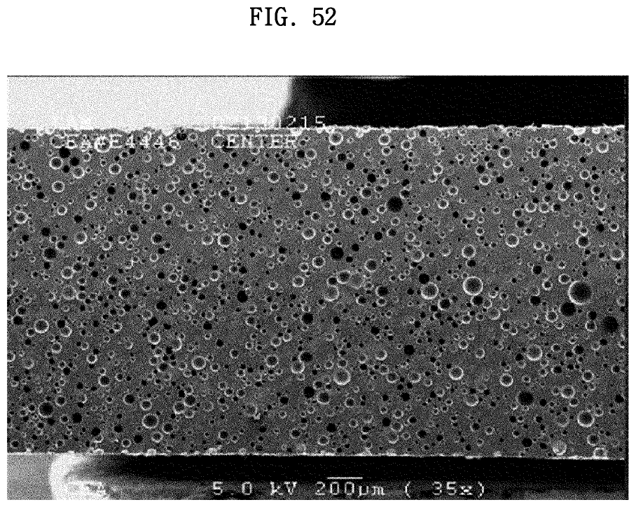

A commercially available IC1010 (product name) polishing pad from Dow Corporation was prepared. The microscope image of the cross section thereof is shown in FIG. 52.

### Test Example 1: Measurement of Removal Rate with Respect to Circumferential Length Per Unit Area

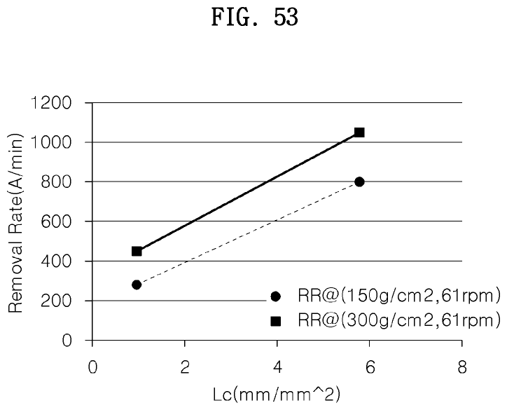

In order to check the effect of the circumferential per unit area on the removal rate characteristics, the removal rate was measured while varying a pressure, the ratio of the polishing area with respect to the total area, and the circumferential length per unit area. The polishing test was performed using an 8-inch oxide wafer and TSO-12 from Soulbrain (KR) that is slurry for oxide. The results thereof are shown in FIGS. 53 to 56.

Here, the pressure, specifically, an apparent contact pressure Pa may be defined as a value obtained by dividing the total load applied to the polishing target substrate by the area of the polishing target substrate by a carrier.

FIG. 53 shows the removal rate in the case where the rotation velocity of the polishing pad is fixed to 61 rpm, the pressure is changed to 150 g/cm² and 300 g/cm², the polishing pad according to Preparation Example 2 is used, and the ratio of the polishing area with respect to the total area is about 2.5%.

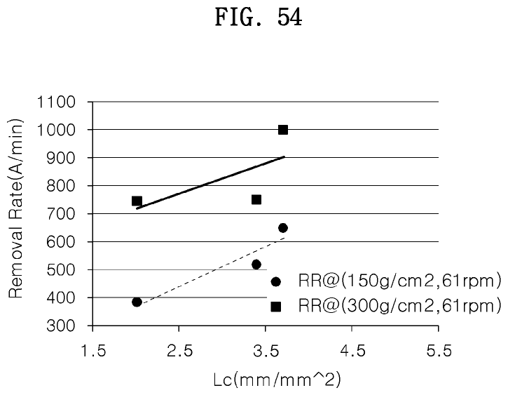

FIG. 54 shows the removal rate in the case where the rotation velocity of the polishing pad is fixed to 61 rpm, the pressure is changed to 150 g/cm² and 300 g/cm², the polishing pad according to Preparation Example 2 is used, and the ratio of the polishing area with respect to the total area is about 5.0%.

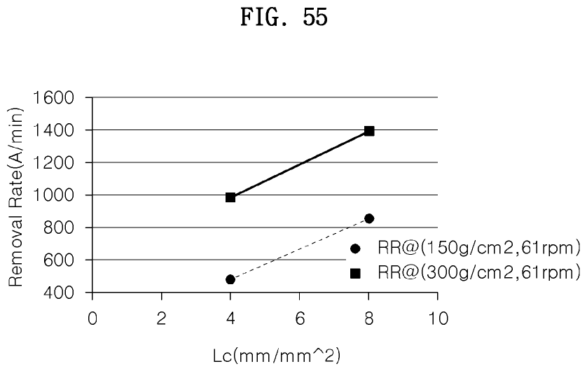

FIG. 55 shows the removal rate in the case where the rotation velocity of the polishing pad is fixed to 61 rpm, the pressure is changed to 150 g/cm² and 300 g/cm², the polishing pad according to Preparation Example 3 is used, and the ratio of the polishing area with respect to the total area is about 10%.

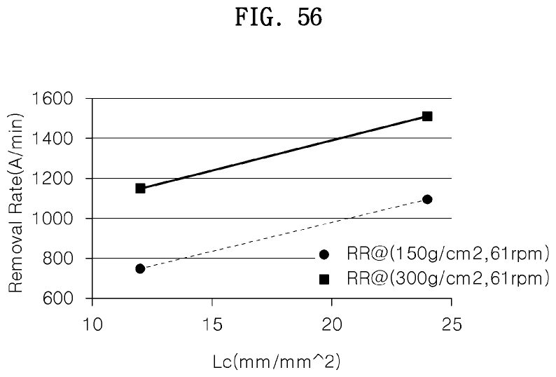

FIG. 56 shows the removal rate in the case where the rotation velocity of the polishing pad is fixed to 61 rpm, the pressure is changed to 150 g/cm² and 300 g/cm², the polishing pad according to Preparation Example 2 is used, and the ratio of the polishing area with respect to the total area is about 30%.

Referring to FIGS. 53 to 56, it is clear that the removal rate increases as the circumferential length of the protrusion pattern increases regardless of the polishing pressure and the area ratio. Further, it is clear that the removal rate tends to increase as the area ratio (the ratio of the polishing area to the total area) increases. Although not illustrated in a graph, it was clear that when the ratio of the polishing area exceeded 50%, the increase in the removal rate slowed down.

In conclusion, it is clear that the removal rate may vary depending on the area ratio and the circumferential length. In particular, it was clear that the circumferential length per unit area was a primary factor affecting the removal rate.

### Test Example 2: Precise Measurement of Removal Rate with Respect to Circumferential Length Per Unit Area

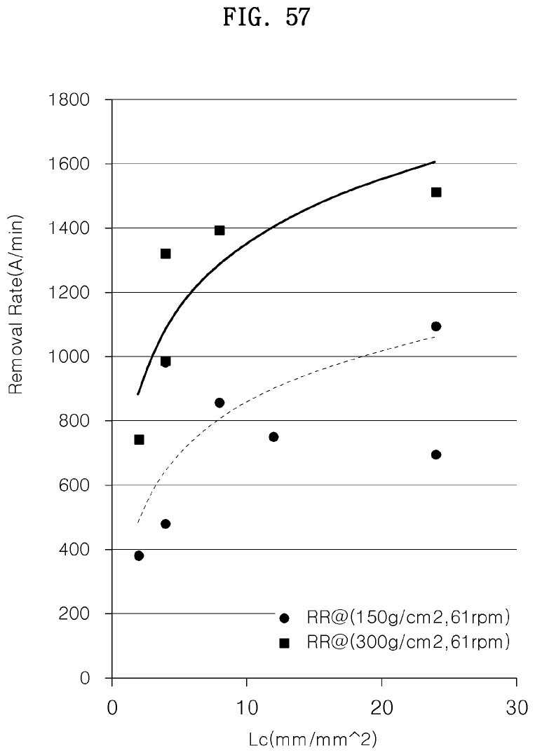

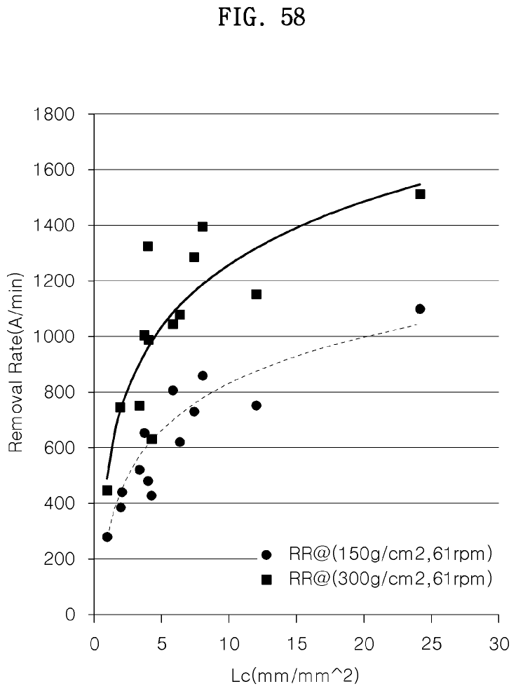

The removal rate with respect to the circumferential length per unit area was precisely measured while further varying the circumferential length per unit area. The results thereof are shown in FIGS. 57 and 58.

FIG. 57 shows data on circular patterns of FIGS. 53 to 55 obtained in the case where the rotation velocity is fixed to 61 rpm, the pressure is changed to 150 g/cm² and 300 g/cm², and the polishing pad (circular protrusion pattern) according to Preparation Example 3 is used, and it is clear that the removal rate is controlled based on the circumferential length of the protrusion pattern per unit area and the ratio of the polishing area.

FIG. 58 shows data collected from Preparation Examples 2 and 3 regardless of the polishing area ratio or the circumferential length per unit area in the case where the rotation velocity is fixed to 61 rpm and the pressure is changed to 150 g/cm² and 300 g/cm².

Referring to FIGS. 57 and 58, it is clear that both the circumferential length per unit area and the ratio of the polishing area are major control factors in controlling the removal rate. However, it is clear that the removal rate increases as the circumferential length per unit area increases, but the increase gradually slows down. Although not illustrated in a graph, it was clear that when the circumferential length per unit area exceeds 50 mm/mm², the removal rate no longer proportionally increases and the increase tends to slow down.

In conclusion, it is clear that the removal rate may vary depending on the circumferential length. In particular, it was clear that the circumferential length per unit area was the primary factor affecting the removal rate.

### Test Example 3: Comparison of Characteristics with Conventional Polishing Pad

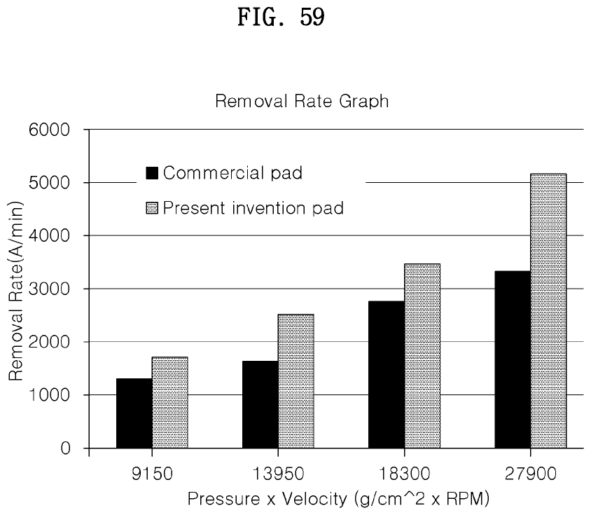

The removal rate was measured and compared using the conventional polishing pad prepared in Comparative Example and the polishing pad of Preparation Example 2 (polishing area ratio of 12.0%). The processing conditions including the pad rotation velocities of 93 rpm and 61 rpm and the polishing pressures of 150 g/cm² and 300 g/cm² were determined as polishing conditions, and HS-9400D from Hitachi (JP) diluted at a ratio of 1:1 was used as polishing slurry. The products of the polishing pressures and the rotation velocities are plotted on the x-axis. The results thereof are shown in FIG. 59.

Referring to FIG. 59, it is clear that the polishing pad according to the present invention is superior to the polishing pad according to Comparative Example in all conditions.

### Test Example 4: Measurement of Planarization Characteristics

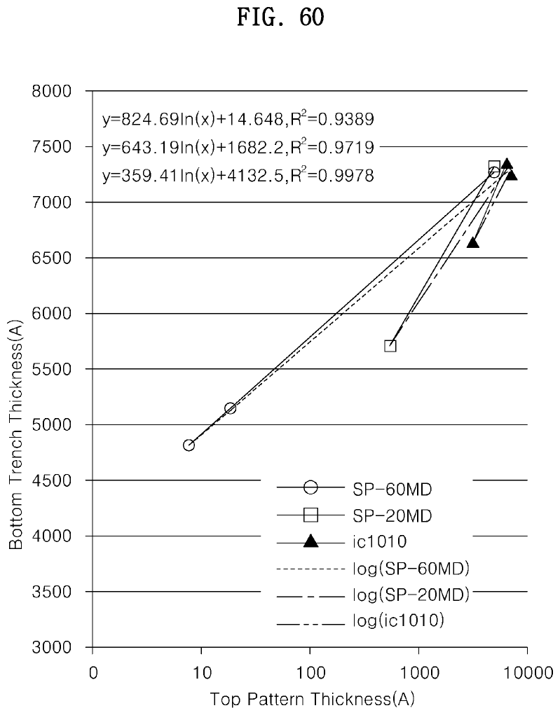

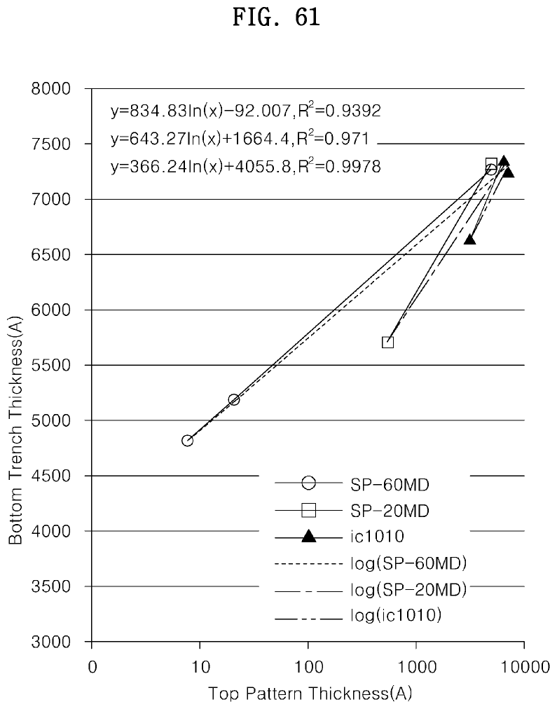

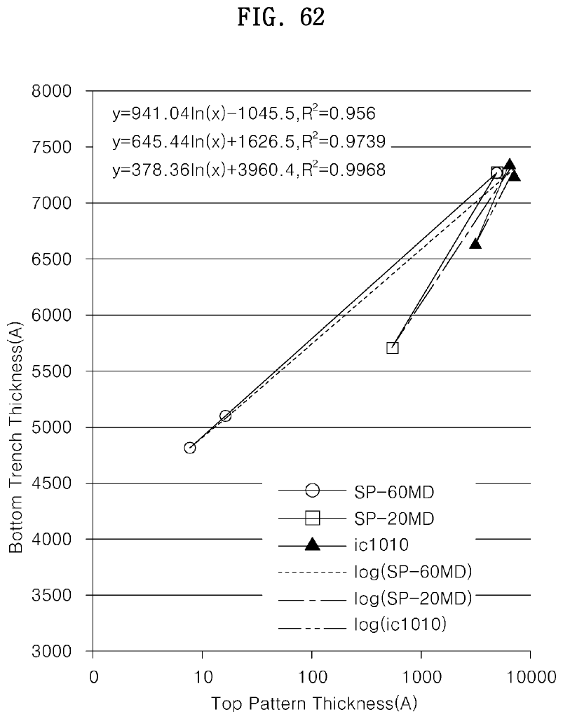

The polishing pad of Preparation Example 2 (polishing area ratio of 12.0%) having sub-patterns having widths of 60 μm and 20 μm (SP-60MD and SP-20MD) were prepared, and the planarization of the overcoating layer of an arbitrary wafer substrate was performed. Further, the planarization of the overcoating layer was performed using the IC1010 polishing pad prepared according to Comparative Example. The results thereof are shown in FIGS. 60 to 62 depending on the widths of the sub-patterns. The patterns in the pattern wafer used in the test have a density of about 50%, and FIGS. 60 to 62 show the case where the line widths of the patterns are 5 μm, 10 μm, and 50 μm, respectively.

In FIGS. 60 to 62, the x-axis represents the thickness of the protruding portion (upper portion) of the overcoating layer, and the y-axis represents the thickness of the recessed portion (lower portion) of the overcoating layer. The slopes of the graphs indicate that a degree of removal of the recessed portion (portion that should not be removed) of the overcoating layer is smaller than a degree of removal of the protruding portion (portion that should be removed) of the overcoating layer, and the planarization characteristics are improved as the slope becomes smaller. That is, when the slope of the graph is 0 (horizontal), it may indicate an ideal polishing pad in which only the protruding portion is removed and the recessed portion is not removed at all.

Referring to FIGS. 60 to 62, in performing planarization of the overcoating layer, the slope in the case of the polishing pad according to the present invention is within a range of about 200 to 400 (SP-60MD) and 200 to 600 (SP-20MD), whereas the slope in the case of the polishing pad according to Comparative Example is within a range of about 800 to 1,000 (in the case of IC1010), which shows that the polishing pad according to the present invention exhibits relatively excellent planarization and polishing selectivity. In particular, it was clear that the planarization was improved when the width of the sub-pattern was small than when the width of the sub-pattern was large.

### Test Example 5: Measurement of Increase in Polishing Temperature

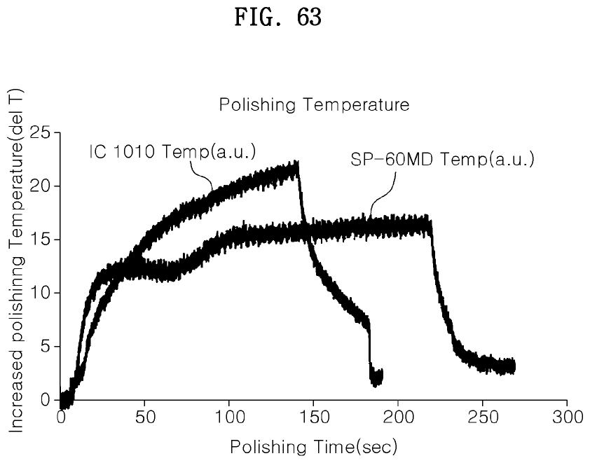

A polishing process was performed using the polishing pad (SP-60MD) according to the present invention and the polishing pad (IC1010) according to Comparative Example, and the increase in polishing temperature with respect to polishing time was measured. The results thereof are shown in FIG. 63.

Referring to FIG. 63, in the case of the polishing pad according to the present invention, the polishing temperature decreases again when the polishing time reaches about 150 seconds, whereas in the case of the polishing pad according to Comparative Example, the temperature decreases when the polishing time reaches about 220 seconds, which shows that a longer period of time is required to stabilize the polishing process. This may be due to the shapes of the protrusion patterns, but the present invention is not limited to any theory.

Although the embodiments have been described above, they are merely examples and not intended to limit the embodiments and it should be appreciated that various modifications and applications not described above may be made by one of ordinary skill in the art without departing from the essential features of the embodiment.

For example, the polishing device according to the present invention may include any one of the polishing pads according to the above-described various embodiments. Further, the polishing pad according to the present invention may have any one of various cross-sectional structures described in other embodiments.

Therefore, it should be understood that the scope of the present invention includes changes, equivalents or substitutes of the technical spirit described above. For example, each component specifically shown in the embodiment of the present invention may be modified and implemented. In addition, it should be understood that differences related to these modifications and applications are within the scope of the present invention as defined in the appended claims.

What is claimed is:

1. A polishing pad comprising:
a support layer; and
a pattern layer disposed on one surface of the support layer, including a plurality of protrusion patterns spaced apart from each other on the support layer, and having a rigidity greater than a rigidity of the support layer.

2. The polishing pad of claim 1, wherein in a plan view, a polishing area occupied by the protrusion patterns is about 1.0% to about 40.0% with respect to a total area.

3. The polishing pad of claim 1, wherein in a unit area in a plan view, a circumferential length per unit area formed by planar circumferences of the protrusion patterns is about 1.0 mm/mm² to about 50.0 mm/mm².

4. The polishing pad of claim 1, wherein a protrusion pattern of the plurality of protrusion patterns includes:
a first portion having a vertical side surface; and
a second portion disposed between the first portion and the support layer and having an inclined sidewall,
wherein a height of the first portion is about 0.01 mm to about 0.5 mm.

5. The polishing pad of claim 1, wherein the protrusion patterns are regularly and repeatedly arranged in a plan view, and are repeatedly arranged along at least two directions.

6. The polishing pad of claim 5, wherein in the plurality of protrusion patterns regularly arranged, a certain protrusion pattern includes a plurality of sub-patterns having a same shape or different shapes,
wherein the plurality of sub-patterns are regularly arranged to form the certain protrusion pattern,
wherein in the plurality of sub-patterns, a certain sub-pattern has an approximately ‘+’ shape, and the plurality of sub-patterns are spaced apart from each other.

7. The polishing pad of claim 5, wherein in the plurality of protrusion patterns regularly arranged, a certain protrusion pattern includes a plurality of sub-patterns having a same shape or different shapes,
the plurality of sub-patterns forming the certain protrusion pattern are regularly arranged, and
a repeated arrangement direction of the plurality of protrusion patterns intersects a repeated arrangement direction of the plurality of sub-patterns.

8. The polishing pad of claim 1, wherein one surface of the polishing pad has a trench formed at least in the pattern layer,
the polishing pad has a circular shape in a plan view,
the trench includes a plurality of first trenches extending radially from a center of the circular polishing pad, and
the first trenches extend at least in a first direction and a second direction perpendicular to the first direction.

9. The polishing pad of claim 8, wherein a maximum depth of the trench is greater than a maximum height of each of the protrusion pattern.

10. The polishing pad of claim 8, wherein the trench further includes a plurality of second trenches arranged concentrically with respect to the center of the circular polishing pad, and a width of each of the second trenches is smaller than a width of each of the first trenches.

11. The polishing pad of claim 10, wherein the trench further includes a plurality of third trenches extending to intersect the first trenches and the second trenches and extending to intersect a tangential direction of a rotation direction of the polishing pad, and
a width of each of the third trenches is smaller than the width of each of the second trenches.

12. The polishing pad of claim 8, wherein the protrusion patterns are regularly and repeatedly arranged in a plan view, and a repeated arrangement direction of the protrusion patterns intersects the first direction and the second direction.

13. The polishing pad of claim 8, wherein the protrusion patterns are regularly and repeatedly arranged in a plan view,
in the plurality of protrusion patterns, a certain protrusion pattern includes a plurality of sub-patterns having a same shape or different shapes,
the plurality of sub-patterns forming the certain protrusion pattern are regularly arranged, and
a repeated arrangement direction of the sub-patterns intersects the first direction and the second direction.

14. The polishing pad of claim 1, wherein the pattern layer further includes:
a plurality of bases spaced apart from each other,
wherein the plurality of protrusion patterns are spaced apart from each other on upper surfaces of the bases,
wherein a separation space between two adjacent bases of the plurality of bases forms a trench, and the one surface of the support layer is at least partially exposed through the separation space.

15. The polishing pad of claim 1, wherein the pattern layer further includes:
a base,
wherein the plurality of protrusion patterns are spaced apart from each other on one surface of the base,
wherein the one surface of the base has a trench, a maximum thickness of the base is about 1.0 mm to about 3.0 mm, and the trench of the base does not penetrate the base.

16. The polishing pad of claim 1, wherein the one surface of the support layer has a trench, and
the trench of the support layer does not overlap the protrusion pattern in a plan view, and a maximum depth of the trench of the support layer is about 1% to about 50% of a maximum thickness of the support layer.

17. The polishing pad of claim 16, wherein the pattern layer further includes:
a plurality of bases spaced apart from each other,
wherein the plurality of protrusion patterns are spaced apart from each other on upper surfaces of the bases,
wherein a separation space between two adjacent bases of the plurality of bases forms a trench, and the trench of the support layer is connected to the trench of the base.

18. The polishing pad of claim 1, wherein the support layer and the pattern layer are made of different materials, and
the polishing pad further comprises: a bonding layer interposed between the support layer and the pattern layer.

19. A polishing device comprising:
a polishing platen configured to rotate; and
a polishing pad disposed on the polishing platen,
wherein the polishing pad includes:
a support layer; and
a pattern layer disposed on one surface of the support layer, including a plurality of protrusion patterns spaced apart from each other on the support layer, and having a rigidity greater than a rigidity of the support layer.

20. A method of preparing a polishing pad, comprising:
unwinding a support layer from an unwinding roll;
disposing a pattern layer on one surface of the support layer, the pattern layer including a plurality of protrusion patterns spaced apart from each other; and
forming a trench at least in the pattern layer such that at least a part of the protrusion patterns is removed.
